(19) United States
(12) Patent Application Publication
(10) Pub. No.: US 2022/0335982 A1
(43) Pub. Date: Oct. 20, 2022

(54) SHARED VERTICAL DIGIT LINE FOR SEMICONDUCTOR DEVICES

(71) Applicant: Micron Technology, Inc., Boise, ID (US)

(72) Inventors: Yuan He, Boise, ID (US); Song Guo, Boise, ID (US)

(21) Appl. No.: 17/234,052

(22) Filed: Apr. 19, 2021

(51) Int. Cl. G11C 5/06; H01L 27/108; H01L 29/423; H01L 29/66; H01L 29/786; H01L 29/06

(52) U.S. Cl. CPC G11C 5/063; H01L 27/10805; H01L 27/1085; H01L 27/10873; H01L 27/10885; H01L 27/10891; H01L 29/42392; H01L 29/66742; H01L 29/78618; H01L 29/0665

(57) ABSTRACT

Systems, methods and apparatus are provided for an array of vertically stacked memory cells having horizontally oriented access devices and access lines, and shared vertically oriented digit line. The access devices having a first source/drain region and a second source drain region separated by a channel region, and gates opposing the channel region. Horizontal oriented access lines are coupled to the gates and separated from a channel region by a gate dielectric. The memory cells have horizontally oriented storage nodes coupled to the second source/drain region of the horizontally oriented access devices. The shared, vertically oriented digit line is shared between two neighboring horizontal access devices and is coupled to the first source/drain regions of the two neighboring horizontally oriented access devices.

### TECHNICAL FIELD

The present disclosure relates generally to memory devices, and more particularly, to a shared vertical digit line for semiconductor devices.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain regions separated by a channel region. A gate may oppose the channel region and be separated therefrom by a gate dielectric. An access line, such as a word line, is electrically connected to the gate of the DRAM cell. A DRAM cell can include a storage node, such as a capacitor cell, coupled by the access device to a shared digit line. The access device can be activated (e.g., to select the cell) by an access line coupled to the access transistor. The capacitor can store a charge corresponding to a data value of a respective cell (e.g., a logic “1” or “0”).

### BRIEF DESCRIPTION OF THE DRAWINGS

FIG. 1 is a schematic illustration of a vertical three dimensional (3D) memory in accordance a number of embodiments of the present disclosure.

FIG. 2 is a perspective view illustrating a portion of a shared vertical digit line for semiconductor devices in accordance with a number of embodiments of the present disclosure.

FIGS. 3A-3B illustrate a portion of a shared vertical digit line for semiconductor devices in accordance with a number of embodiments of the present disclosure.

FIG. 4 is a cross-sectional view for forming arrays of vertically stacked memory cells, at multiple stages of a semiconductor fabrication process, for forming arrays of vertically stacked memory cells, having a shared vertical digit line for semiconductor devices and horizontally oriented access lines in accordance with a number of embodiments of the present disclosure.

FIGS. 5A-5B illustrate an example method, at one stage of a semiconductor fabrication process, for forming arrays of vertically stacked memory cells, having a shared vertical digit line for semiconductor devices and horizontally oriented access lines, in accordance with a number of embodiments of the present disclosure.

FIGS. 6A to 6E illustrate an example method, at another stage of a semiconductor fabrication process, for forming arrays of vertically stacked memory cells, having a shared vertical digit line for semiconductor devices and horizontally oriented access lines, in accordance with a number of embodiments of the present disclosure.

FIGS. 7A to 7E illustrate an example method, at another stage of a semiconductor fabrication process, for forming arrays of vertically stacked memory cells, having a shared vertical digit line for semiconductor devices and horizontally oriented access lines, in accordance with a number of embodiments of the present disclosure.

FIGS. 8A to 8E illustrate an example method, at another stage of a semiconductor fabrication process, for forming arrays of vertically stacked memory cells, having a shared vertical digit line for semiconductor devices and horizontally oriented access lines, in accordance with a number of embodiments of the present disclosure.

FIGS. 9A to 9E illustrate an example method, at another stage of a semiconductor fabrication process, for forming arrays of vertically stacked memory cells, having a shared vertical digit line for semiconductor devices and horizontally oriented access lines, in accordance with a number of embodiments of the present disclosure.

FIGS. 10A to 10E illustrate an example method, at another stage of a semiconductor fabrication process, for forming arrays of vertically stacked memory cells, having a shared vertical digit line for semiconductor devices and horizontally oriented access lines, in accordance with a number of embodiments of the present disclosure.

FIGS. 11A to 11E illustrate an example method, at another stage of a semiconductor fabrication process, for forming arrays of vertically stacked memory cells, having a shared vertical digit line for semiconductor devices and horizontally oriented access lines, in accordance with a number of embodiments of the present disclosure.

FIGS. 12A to 12E illustrate an example method, at another stage of a semiconductor fabrication process, for forming arrays of vertically stacked memory cells, having a shared vertical digit line for semiconductor devices and horizontally oriented access lines, in accordance with a number of embodiments of the present disclosure.

FIGS. 13A to 13E illustrate an example method, at another stage of a semiconductor fabrication process, for forming arrays of vertically stacked memory cells, having a shared vertical digit line for semiconductor devices and horizontally oriented access lines, in accordance with a number of embodiments of the present disclosure.

FIG. 14 is an example of a multiplexor for a semiconductor device, in accordance a number of embodiments of the present disclosure.

FIG. 15 is an example of a multiplexor coupled to an example horizontally oriented access device and access lines and shared vertically oriented digit lines for semiconductor devices, in accordance with a number of embodiments of the present disclosure.

FIG. 16 is a block diagram of an apparatus in the form of a computing system including a memory device 1693 in accordance with a number of embodiments of the present disclosure.

### DETAILED DESCRIPTION

Embodiments of the present disclosure describe a shared vertical digit line for semiconductor devices. A shared vertically oriented digit line is formed with horizontally oriented access devices and access lines in an array of vertically stacked memory cells. The horizontal access devices are integrated with horizontally oriented access lines and integrated with a shared vertically oriented digit line. The shared vertically oriented digit line which is shared between two horizontal access devices, is coupled to the first source/drain regions of the two horizontally oriented access devices. This further provides improved array efficiency for the digit line.

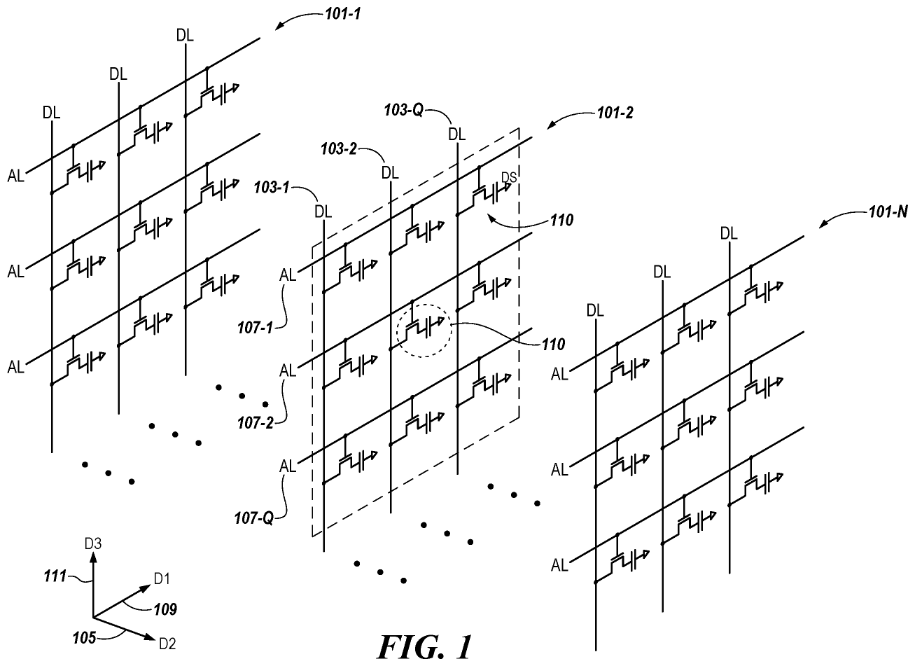

FIG. 1 is a block diagram of an apparatus in accordance a number of embodiments of the present disclosure. FIG. 1 illustrates a circuit diagram showing a cell array of a three dimensional (3D) semiconductor memory device according to embodiments of the present disclosure. FIG. 1 illustrates a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays, e.g., sub cell array 101-2, may include a plurality of access lines 107-1, 107-2, . . . , 107-Q (which also may be referred to a wordlines). Also, each of the sub cell arrays, e.g., sub cell array 101-2, may include a plurality of shared digit lines 103-1, 103-2, . . . , 103-Q (which also may be referred to as bitlines, data lines, or sense lines). In FIG. 1, the access lines 107-1, 107-2, . . . , 107-Q are illustrated extending in a first direction (D1) 109 and the shared digit lines 103-1, 103-2, . . . , 103-Q are illustrated extending in a third direction (D3) 111.

According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the shared digit lines 103-1, 103-2, . . . , 103-Q are extending in a vertical direction, e.g., third direction (D3) 111.

A memory cell, e.g., 110, may include an access device, e.g., access transistor, and a storage node located at an intersection of each access line 107-1, 107-2, . . . , 107-Q and each shared digit line 103-1, 103-2, . . . , 103-Q. Memory cells may be written to, or read from, using the access lines 107-1, 107-2, . . . , 107-Q and shared digit lines 103-1, 103-2, . . . , 103-Q. The access lines 107-1, 107-2, . . . , 107-Q may conductively interconnect memory cells along horizontal rows of each sub cell array 101-, 101-2, . . . , 101-N, and the digit lines 103-1, 103-2, . . . , 103-Q may conductively interconnect memory cells along vertical columns of each sub cell array 101-, 101-2, . . . , 101-N. One memory cell, e.g. 110, may be located between one access line, e.g., 107-2, and one shared digit line, e.g., 103-2. Each memory cell may be uniquely addressed through a combination of an access line 107-1, 107-2, . . . , 107-Q and a shared digit line 103-1, 103-2, . . . , 103-Q.

The access lines 107-1, 107-2, . . . , 107-P may be or include conducting patterns (e.g., metal lines) disposed on and spaced apart from a substrate. The access lines 107-1, 107-2, . . . , 107-Q may extend in a first direction (D1) 109. The access lines 107-1, 107-2, . . . , 107-Q in one sub cell array, e.g., 101-2, may be spaced apart from each other in a vertical direction, e.g., in a third direction (D3) 111.

The shared digit lines 103-1, 103-2, . . . , 103-Q may be or include conductive patterns (e.g., metal lines) extending in a vertical direction with respect to the substrate, e.g., in a third direction (D3) 111. The shared digit lines in one sub cell array, e.g., 101-2, may be spaced apart from each other in the first direction (D1) 109.

A gate of a memory cell, e.g., memory cell 110, may be connected to an access line, e.g., 107-2, and a first conductive node, e.g., first source/drain region, of an access device, e.g., transistor, of the memory cell 110 may be connected to a shared digit line, e.g., 103-2. Each of the memory cells, e.g., memory cell 110, may be connected to a storage node, e.g., capacitor. A second conductive node, e.g., second source/drain region, of the access device, e.g., transistor, of the memory cell 110 may be connected to the storage node, e.g., capacitor. While first and second source/drain region reference are used herein to denote two separate and distinct source/drain regions, it is not intended that the source/drain region referred to as the “first” and/or “second” source/drain regions have some unique meaning. It is intended only that one of the source/drain regions is connected to shared digit line, e.g., 103-2, and the other may be connected to a storage node.

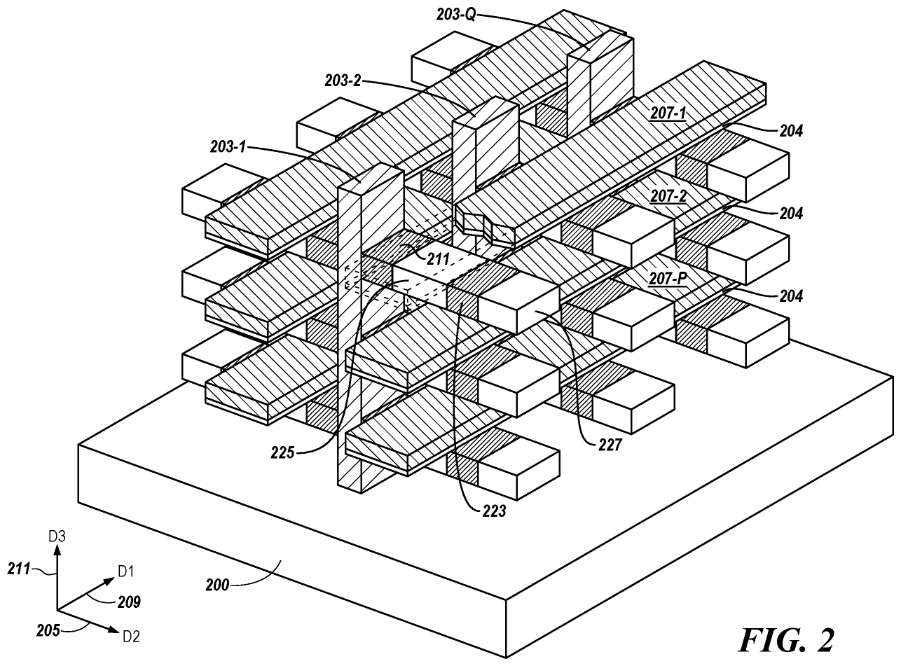

FIG. 2 illustrates a perspective view showing a three dimensional (3D) semiconductor memory device, e.g., a portion of a sub cell array 101-2 shown in FIG. 1 as a vertically oriented stack of memory cells in an array, according to some embodiments of the present disclosure. FIG. 2 illustrates a perspective view showing unit cell, e.g., memory cell 110 shown in FIG. 1, of the 3D semiconductor memory device shown in FIG. 2.

As shown in FIG. 2, a substrate 200 may have formed thereon one of the plurality of sub cell arrays, e.g., 101-2, described in connection with FIG. 1. For example, the substrate 200 may be or include a silicon substrate, a germanium substrate, or a silicon-germanium substrate, etc. Embodiments, however, are not limited to these examples.

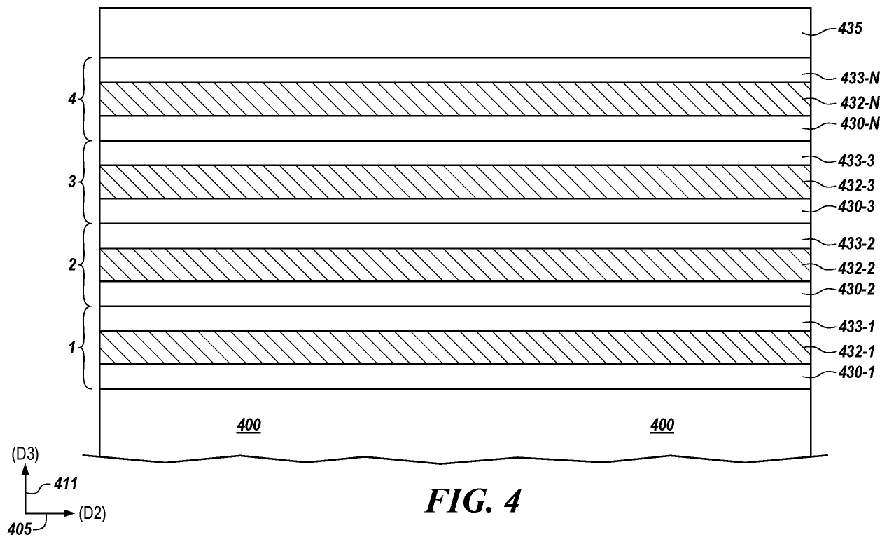

As shown in the example embodiment of FIG. 2, the substrate 200 may have fabricated thereon a vertically oriented stack of memory cells, e.g., memory cell 110 in FIG. 1, extending in a vertical direction, e.g., third direction (D3) 111. According to some embodiments the vertically oriented stack of memory cells may be fabricated such that each memory cell, e.g., memory cell 110 in FIG. 1, is formed on plurality of vertical levels, e.g., a first level (L1), a second level (L2), and a third level (L3). The repeating, vertical levels, L1, L2, and L3, may be arranged, e.g., “stacked”, a vertical direction, e.g., third direction (D3) 111 shown in FIG. 1. Each of the repeating, vertical levels, L1, L2, and L3 may include a plurality of discrete components, e.g., regions, to the horizontally oriented access devices 230, e.g., transistors, and storage nodes, e.g., capacitors, including access line 107-1, 107-2, . . . , 107-Q connections and shared digit line 103-1, 103-2, . . . , 103-Q connections. The plurality of discrete components to the horizontally oriented access devices 230, e.g., transistors, may be formed in a plurality of iterations of vertically, repeating layers within each level, as described in more detail below in connection with FIGS. 4A-4K, and may extend horizontally in the second direction (D2) 205, analogous to second direction (D2) 105 shown in FIG. 1.

The plurality of discrete components to the horizontally oriented access devices 230, e.g., transistors, may include a first source/drain region 221 and a second source/drain region 223 separated by a channel region 225, extending laterally in the second direction (D2) 205, and formed in a body of the access devices. In some embodiments, the channel region 225 may include silicon, germanium, silicon-germanium, and/or indium gallium zinc oxide (IGZO). In some embodiments, the first and the second source/drain regions, 221 and 223, can include an n-type dopant region formed in a p-type doped body to the access device to form an n-type conductivity transistor. In some embodiments, the first and the second source/drain regions, 221 and 223, may include a p-type dopant formed within an n-type doped body to the access device to form a p-type conductivity transistor. By way of example, and not by way of limitation, the n-type dopant may include Phosphorous (P) atoms and the p-type dopant may include atoms of Boron (B) formed in an oppositely doped body region of polysilicon semiconductor material. Embodiments, however, are not limited to these examples.

The storage node 227, e.g., capacitor, may be connected to one respective end of the access device. As shown in FIG. 2, the storage node 227, e.g., capacitor may be connected to the second source/drain region 223 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1, may similarly extend in the second direction (D2) 205, analogous to second direction (D2) 105 shown in FIG. 1.

As shown in FIG. 2 a plurality of horizontally oriented access lines 207-1, 207-2, . . . , 207-Q extend in the first direction (D1) 209, analogous to the first direction (D1) 109 in FIG. 1. The plurality of horizontally oriented access lines 207-1, 207-2, . . . , 207-Q may be analogous to the access lines 107-1, 107-2, . . . , 107-Q shown in FIG. 1. The plurality of horizontally oriented access lines 207-1, 207-2, . . . , 207-Q may be arranged, e.g., “stacked”, along the third direction (D3) 211. The plurality of horizontally oriented access lines 207-1, 207-2, . . . , 207-Q may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, (L1) 213-1, (L2) 213-2, and (L3) 213-P, the horizontally oriented memory cells, e.g., memory cell 110 in FIG. 1, may be spaced apart from one another horizontally in the first direction (D1) 209. However, as described in more detail below in connection with FIG. 4 et. seq., the plurality of discrete components to the horizontally oriented access devices 230, e.g., first source/drain region 221 and second source/drain region 223 separated by a channel region 225, extending laterally in the second direction (D2) 205, and the plurality of horizontally oriented access lines 207-1, 207-2, . . . , 207-Q extending laterally in the first direction (D1) 209, may be formed within different vertical layers within each level. For example, the plurality of horizontally oriented access lines 207-1, 207-2, . . . , 207-Q, extending in the first direction (D1) 209, may be formed on a top surface opposing and electrically coupled to the channel regions 225, separated therefrom by a gate dielectric, and orthogonal to horizontally oriented access devices 230, e.g., transistors, extending in laterally in the second direction (D2) 205. In some embodiments, the plurality of horizontally oriented access lines 207-1, 207-2, . . . , 207-Q, extending in the first direction (D1) 209 are formed in a higher vertical layer, farther from the substrate 200, within a level, e.g., within level (L1), than a layer in which the discrete components, e.g., first source/drain region 221 and second source/drain region 223 separated by a channel region 225, of the horizontally oriented access device are formed.

As shown in the example embodiment of FIG. 2, the shared digit lines, 203-1, 203-2, . . . , 203-Q, extend in a vertical direction with respect to the substrate 200, e.g., in a third direction (D3) 211. Further, as shown in FIG. 2, the shared digit lines, 203-1, 203-2, . . . , 203-Q, in one sub cell array, e.g., sub cell array 101-2 in FIG. 1, may be spaced apart from each other in the first direction (D1) 209. The shared digit lines, 203-1, 203-2, . . . , 203-Q, may be provided, extending vertically relative to the substrate 200 in the third direction (D3) 211 in vertical alignment with source/drain regions to serve as first source/drain regions 221 or, as shown, be vertically adjacent first source/drain regions 221 for each of the horizontally oriented access devices 230, e.g., transistors, extending laterally in the second direction (D2) 205, but adjacent to each other on a level, e.g., first level (L1), in the first direction (D1) 209. Each of the shared digit lines, 203-1, 203-2, . . . , 203-Q, may vertically extend, in the third direction (D3), adjacent first source/drain regions 221, of respective ones of the plurality of horizontally oriented access devices 230, e.g., transistors, that are vertically stacked. In some embodiments, the plurality of shared vertically oriented digit lines 203-1, 203-2, . . . , 203-Q, extending in the third direction (D3) 211, may be connected to side surfaces of the first source/drain regions 221 directly and/or through additional contacts including metal silicides.

For example, and as shown in more detail in FIG. 2, a first one of the shared vertically extending digit lines, e.g., 203-1, may be adjacent a first source/drain region 221 to a first one of the horizontally oriented access devices 230, e.g., transistors, in the first level (L1) 213-1, a first source/drain region 221 of a first one of the horizontally oriented access devices 230, e.g., transistors, in the second level (L2) 213-2, and a first source/drain region 221 a first one of the horizontally oriented access devices 230, e.g., transistors, in the third level (L3) 213-P, etc. Similarly, a second one of the shared vertically extending digit lines, e.g., 203-2, may be adjacent a first source/drain region 221 of a second one of the horizontally oriented access devices 230, e.g., transistors, in the first level (L1) 213-1, spaced apart from the first one of horizontally oriented access devices 230, e.g., transistors, in the first level (L1) 213-1 in the first direction (D1) 209. And the second one of the shared vertically extending digit lines, e.g., 203-2, may be adjacent a first source/drain region 221 of a second one of the horizontally oriented access devices 230, e.g., transistors, in the second level (L2) 213-2, and a first source/drain region 221 of a second one of the horizontally oriented access devices 230, e.g., transistors, in the third level (L3) 213-P, etc. Embodiments are not limited to a particular number of levels.

The shared vertically extending digit lines, 203-1, 203-2, . . . , 203-Q, may include a conductive material, such as, for example, one of a doped semiconductor material, a conductive metal nitride, metal, and/or a metal-semiconductor compound. The shared digit lines, 203-1, 203-2, . . . , 203-Q, may correspond to shared digit lines (DL) described in connection with FIG. 1.

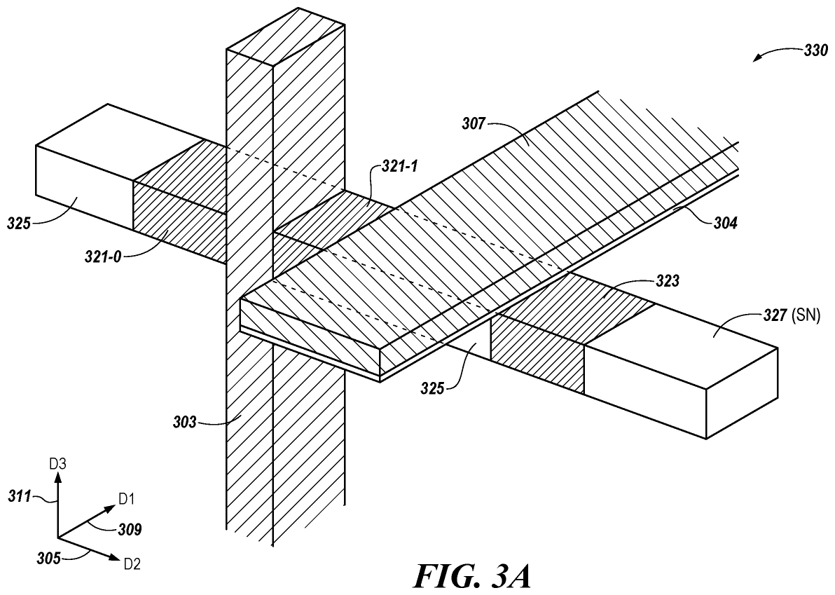

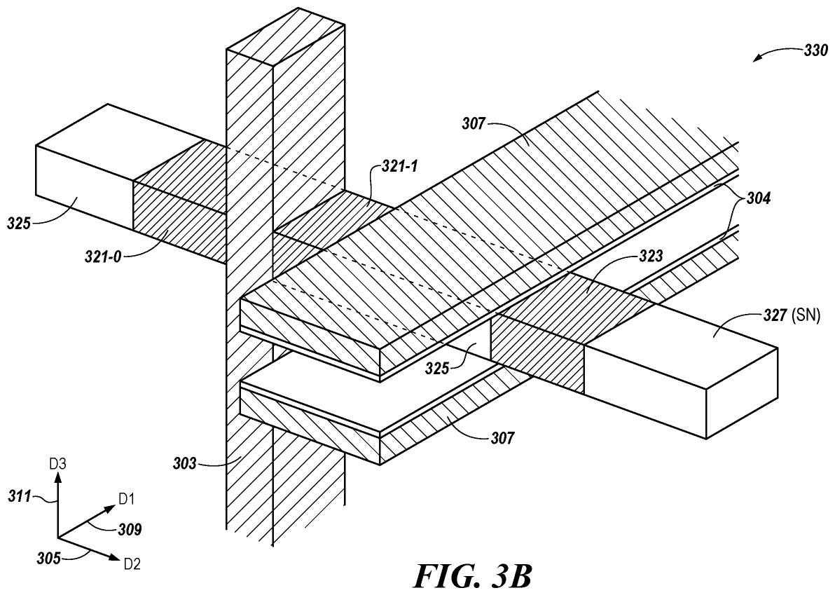

FIG. 3A illustrates in more detail a unit cell, e.g., memory cell 110 in FIG. 1, of the vertically stacked array of memory cells, e.g., within a sub cell array 101-2 in FIG. 1, according to some embodiments of the present disclosure. As shown in FIG. 3A, the first and the second source/drain regions, 321 and 323, may be impurity doped regions to the laterally oriented access devices 330, e.g., transistors. The first and the second source/drain regions, 321 and 323, may be analogous to the first and the second source/drain regions 221 and 223 shown in FIG. 2. The first and the second source/drain regions, 321 and 323, may be formed from an n-type or p-type dopant doped in the body region. Embodiments are not so limited.

For example, for an n-type conductivity transistor construction the body region of the horizontally oriented access devices 330, e.g., transistors, may be formed of a low doped p-type (p−) semiconductor material. In one embodiment, the body region and the channel 325 separating the first and the second source/drain regions, 321 and 323, may include a low doped, p-type (e.g., low dopant concentration (p−)) polysilicon material consisting of boron (B) atoms as an impurity dopant to the polycrystalline silicon. The first and the second source/drain regions, 321 and 323, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In₂O₃), or indium tin oxide (In₂₋ₓSnₓO₃), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 321 and 321, may include a high dopant concentration, n-type conductivity impurity (e.g., high dopant (n+)) doped in the first and the second source/drain regions, 321 and 323. In some embodiments, the high dopant, n-type conductivity first and second drain regions 321 and 323 may include a high concentration of phosphorus (P) atoms deposited therein. Embodiments, however, are not limited to this example. In other embodiments, the horizontally oriented access devices 330, e.g., transistors, may be of a p-type conductivity construction in which case the impurity, e.g., dopant, conductivity types would be reversed.

The gate dielectric material 304 may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 304 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 3A, a shared digit line, e.g., 303-1, analogous to the shared digit lines 203-1, 203-2, . . . , 203-Q in FIGS. 2 and 103-1, 103-2, . . . , 103-Q in FIG. 1, may be vertically extending in the third direction (D3) 311 adjacent the first source/drain region 321 in the body to the horizontally oriented access devices 330, e.g., transistors horizontally conducting between the first and the second source/drain regions 321 and 323 along the second direction (D2) 305.

FIG. 3B illustrates a unit cell, e.g., memory cell 110 in FIG. 1, of the vertically stacked array of memory cells, e.g., within a sub cell array 101-2 in FIG. 1 having a dual gate horizontal access device structure. As shown in FIG. 3B, the first and the second source/drain regions, 321 and 323, may be impurity doped regions to the horizontally oriented access devices 330, e.g., transistors. The first and the second source/drain regions, 321 and 323, may be analogous to the first and the second source/drain regions 221 and 223 shown in FIG. 2 and the first and the second source/drain regions 321 and 323 shown in FIG. 3A. The first and the second source/drain regions may be separated by a channel 325 formed in a body of semiconductor material, e.g., body region, of the horizontally oriented access devices 330, e.g., transistors. The first and the second source/drain regions, 321 and 323, may be formed from an n-type or p-type dopant doped in the body region. Embodiments are not so limited.

As shown in the example embodiment of FIG. 3B, a shared digit line, e.g., 303-1, analogous to the shared digit lines 203-1, 203-2, . . . , 203-Q in FIGS. 2 and 103-1, 103-2, . . . , 103-Q in FIG. 1, may be vertically extending in the third direction (D3) 311 adjacent the first source/drain region 321 in the body to the horizontally oriented access devices 330, e.g., transistors horizontally conducting between the first and the second source/drain regions 321 and 323 along the second direction (D2) 305.

FIG. 3B shows an example embodiment having a dual gate structure wherein the horizontally oriented access devices 330 are formed with the conductive gate material having a top portion above the channel region 325 and a bottom portion below the channel region 325 of the semiconductor material. In one embodiment, the horizontally oriented access devices 330 may be formed as gate all around (GAA) horizontal access devices with the conductive gate material fully around every surface of the channel region 325 formed in the body of the semiconductor material.

FIG. 4 is a cross-sectional view, at one stage of a semiconductor fabrication process, for forming arrays of vertically stacked memory cells, having a shared vertical digit line for semiconductor devices and horizontally oriented access lines, such as illustrated in FIGS. 1-3, and in accordance with a number of embodiments of the present disclosure.

In the example embodiment shown in the example of FIG. 4, the method comprises depositing alternating layers of a first dielectric material, 430-1, 430-2, . . . , 430-N (collectively referred to as first dielectric material 430), a first semiconductor material having a first-type dopant (e.g., p-type dopant such as Boron (B)) , 432-1, 432-2, . . . , 432-N (collectively referred to as first semiconductor material 432), and a second dielectric material, 433-1, 433-2, . . . , 433-N (collectively referred to as second dielectric 433), in repeating iterations to form a vertical stack 401 on a working surface of a semiconductor substrate 400. In one embodiment, the first dielectric material 430 can be deposited to have a thickness, e.g., vertical height in the third direction (D3), in a range of twenty (20) nanometers (nm) to sixty (60) nm. In one embodiment, the first semiconductor material 432 can be deposited to have a thickness, e.g., vertical height, in a range of twenty (20) nm to one hundred (100) nm. In one embodiment, the second dielectric material 433 can be deposited to have a thickness, e.g., vertical height, in a range of ten (10) nm to thirty (30) nm. Embodiments, however, are not limited to these examples. As shown in FIG. 4, a vertical direction 411 is illustrated as a third direction (D3), e.g., z-direction in an x-y-z coordinate system, analogous to the third direction (D3), among first, second, and third directions, shown in FIGS. 1-3.

In some embodiments, the first dielectric material, 430-1, 430-2, . . . , 430-N, may be an interlayer dielectric (ILD). By way of example, and not by way of limitation, the first dielectric material, 430-1, 430-2, . . . , 430-N, may comprise an oxide material, e.g., SiO₂. In another example the first dielectric material, 430-1, 430-2, . . . , 430-N, may comprise a silicon nitride (Si₃N₄) material (also referred to herein as “SiN”). In another example the first dielectric material, 430-1, 430-2, . . . , 430-N, may comprise a silicon oxy-carbide (SiOₓC_{y}) material. In another example the first dielectric material, 430-1, 430-2, . . . , 430-N, may include silicon oxy-nitride (SiOₓN_{y}) material (also referred to herein as “SiON”), and/or combinations thereof. Embodiments are not limited to these examples.

In some embodiments, the first semiconductor material, 432-1, 432-2, . . . , 432-N, may comprise a silicon (Si) material in a polycrystalline and/or amorphous state. The first semiconductor material, 432-1, 432-2, . . . , 432-N, may be a low doped, p-type (p−) silicon material. The first semiconductor material, 432-1, 432-2, . . . , 432-N, may be formed by gas phase doping a first-type dopant. For example, the first semiconductor material, 432-1, 432-2, . . . , 432-N, may be formed by gas phase doping boron atoms (B), as an impurity dopant, at a low concentration to form the low doped, p-type (p−) silicon material. The low doped, p-type (p−) silicon material may be a polysilicon material. Embodiments, however, are not limited to these examples.

In some embodiments, the second dielectric material, 433-1, 433-2, . . . , 433-N, may be an interlayer dielectric (ILD). By way of example, and not by way of limitation, the second dielectric material, 433-1, 433-2, . . . , 433-N, may comprise a nitride material. The nitride material may be a silicon nitride (Si₃N₄) material (also referred to herein as “SiN”). In another example the second dielectric material, 433-1, 433-2, . . . , 433-N, may comprise a silicon oxy-carbide (SiOC) material. In another example the second dielectric material, 433-1, 433-2, . . . , 433-N, may include silicon oxy-nitride (SiON), and/or combinations thereof. Embodiments are not limited to these examples. However, according to embodiments, the second dielectric material, 433-1, 433-2, . . . , 433-N, is purposefully chosen to be different in material or composition than the first dielectric material, 430-1, 430-2, . . . , 430-N, such that a selective etch process may be performed on one of the first and second dielectric layers, for example the other one of the first and the second dielectric layers and/or first semiconductor material 432, e.g, the second SiN dielectric material, 433-1, 433-2, . . . , 433-N, may be selectively etched relative to the first semiconductor material, 432-1, 432-2, . . . , 432-N, and a first oxide dielectric material, 430-1, 430-2, . . . , 430-N.

The repeating iterations of alternating first dielectric material, 430-1, 430-2, . . . , 430-N layers, first semiconductor material, 432-1, 432-2, . . . , 432-N layers, and second dielectric material, 433-1, 433-2, . . . , 433-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of a first dielectric material, a first semiconductor material, and a second dielectric material, in repeating iterations to form the vertical stack 401.

The layers may occur in repeating iterations vertically. In the example of FIG. 4, three tiers, numbered 1, 2, and 3, of the repeating iterations are shown. For example, the stack may include: a first tier having a first dielectric material 430-1, a first semiconductor material 432-1, and a second dielectric material 433-1; a second tier having a first dielectric material 430-2, a first semiconductor material 432-2, and a second dielectric material 433-2; and a third tier having a first dielectric material 430-3, a first semiconductor material 432-3, and a second dielectric material 433-3. As such, a stack may include: a first oxide material 430-1, a first first semiconductor material 432-1, a first nitride material 433-1, a second oxide material 430-2, a second first semiconductor material 432-2, a second nitride material 433-2, a third oxide material 430-3, a third first semiconductor material 432-3, and a third nitride material 433-3 in further repeating iterations. Embodiments, however, are not limited to this example and more or fewer repeating iterations may be included.

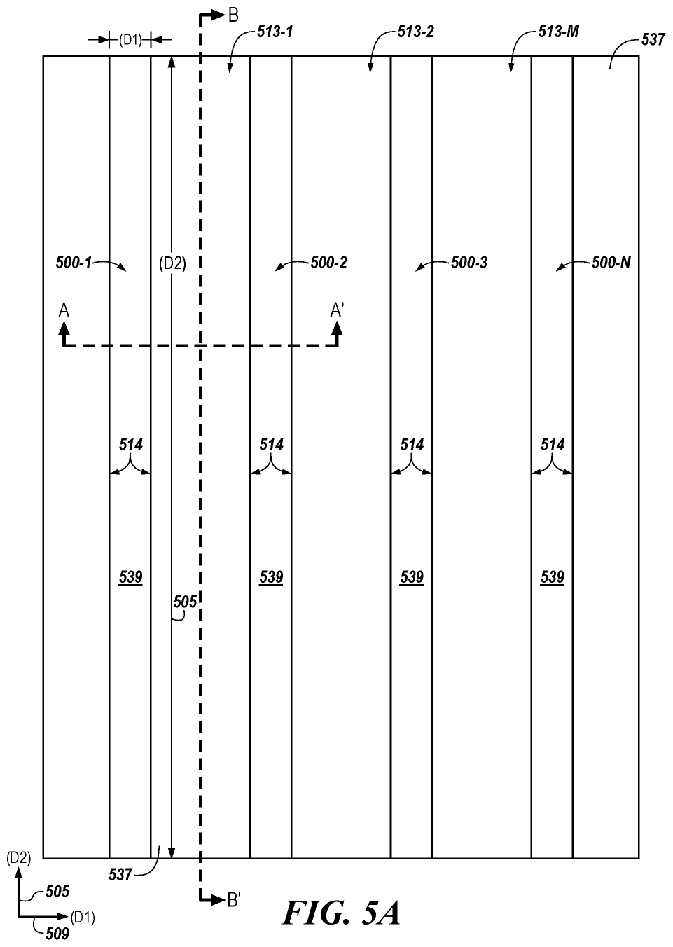

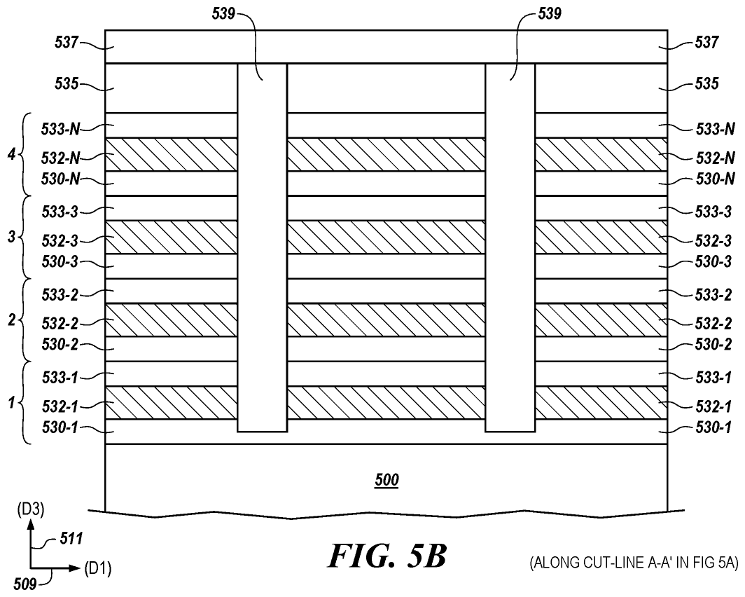

FIG. 5A illustrates an example method, at one stage of a semiconductor fabrication process, for forming arrays of vertically stacked memory cells, having a shared vertical digit line for semiconductor devices and horizontally oriented access lines, such as illustrated in FIGS. 1-3, and in accordance with a number of embodiments of the present disclosure. FIG. 5A illustrates a top down view of a semiconductor structure, at a particular point in time, in a semiconductor fabrication process, according to one or more embodiments. In the example embodiment shown in the example of FIG. 5A, the method comprises using an etchant process to form a plurality of first vertical openings 500, having a first horizontal direction axis (D1) 509 and a second horizontal direction axis (D2) 505, through the vertical stack to the substrate. In one example, as shown in FIG. 5A, the plurality of first vertical openings 500 are extending predominantly in the second horizontal direction axis (D2) 505 and may form elongated vertical, pillar columns 513-1, 513-2, . . . , 513-M (collectively and/or independently referred to as 513), with sidewalls 514 in the vertical stack. The plurality of first vertical openings 500 may be formed using photolithographic techniques to pattern a photolithographic mask 535, e.g., to form a hard mask (HM), on the vertical stack prior to etching the plurality of first vertical openings 500. Similar semiconductor process techniques may be used at other points of the semiconductor fabrication process described herein.

The openings 500 may be filled with a third dielectric material 539. In one example, a spin on dielectric process may be used to fill the openings 500. In one embodiment, the third dielectric material 539 may be an oxide material. However, embodiments are not so limited. In some embodiments, third dielectric material 539 may be formed from a different material than first dielectric material 530. For example, the oxide material used to form third dielectric material 539 may be different from the oxide material used to form first dielectric material 530. In some embodiments, dielectric material 539 may be formed from a same material as the first and/or second dielectric material 530/533.

FIG. 5B is a cross sectional view, taken along cut-line A-A′ in FIG. 5A, showing another view of the semiconductor structure at a particular time in the semiconductor fabrication process. The cross sectional view shown in FIG. 5B shows the repeating iterations of alternating layers of a first dielectric material, 530-1, 530-2, . . . , 530-N, a first semiconductor material, 532-1, 532-2, . . . , 532-N, and a second dielectric material, 533-1, 533-2, . . . , 533-N, on a semiconductor substrate 500 to form the vertical stack, e.g. 401 as shown in FIG. 4.

As shown in FIG. 5B, a plurality of first vertical openings may be formed through the layers within the vertically stacked memory cells to expose vertical sidewalls in the vertical stack and form elongated vertical pillar columns 513 and then filled with a third dielectric material 539. The first vertical openings may be formed through the repeating iterations of the oxide material 530, the first semiconductor material 532, and the nitride material 533. As such, the first vertical openings may be formed through the first oxide material 530-1, the first semiconductor material 532-1, the first nitride material 533-1, the second oxide material 530-2, the second semiconductor material 532-2, the second nitride material 533-2, the third oxide material 530-3, the third semiconductor material 532-3, and the third nitride material 533-3. Embodiments, however, are not limited to the vertical opening(s) shown in FIG. 5B. Multiple vertical openings may be formed through the layers of materials. The first vertical openings may be formed to expose vertical sidewalls in the vertical stack. The first vertical openings may extend along a second horizontal direction axis (D2) 505 to form elongated vertical, pillar columns 513 with first vertical sidewalls in the vertical stack and then filled with third dielectric 539.

As shown in FIG. 5B, a third dielectric material 539, such as an oxide or other suitable spin on dielectric (SOD), may be deposited in the first vertical openings, using a process such as CVD, to fill the first vertical openings. Third dielectric material 539 may also be formed from a silicon nitride (Si₃N₄) material. In another example, the third dielectric material 539 may include silicon oxy-nitride (SiOₓN_{y}), and/or combinations thereof. Embodiments are not limited to these examples. The plurality of first vertical openings may be formed using photolithographic techniques to pattern a photolithographic mask 535, e.g., to form a hard mask (HM), on the vertical stack prior to etching the plurality of first vertical openings. In one embodiment, hard mask 537 may be deposited over third dielectric material 539. In some embodiments, a subsequent photolithographic material 537, e.g., hard mask, may be deposited using CVD and planarized using CMP to cover and close the first vertical openings over the vertical stack and the previous hard mask 537. Similar semiconductor process techniques may be used at other points of the semiconductor fabrication process described herein.

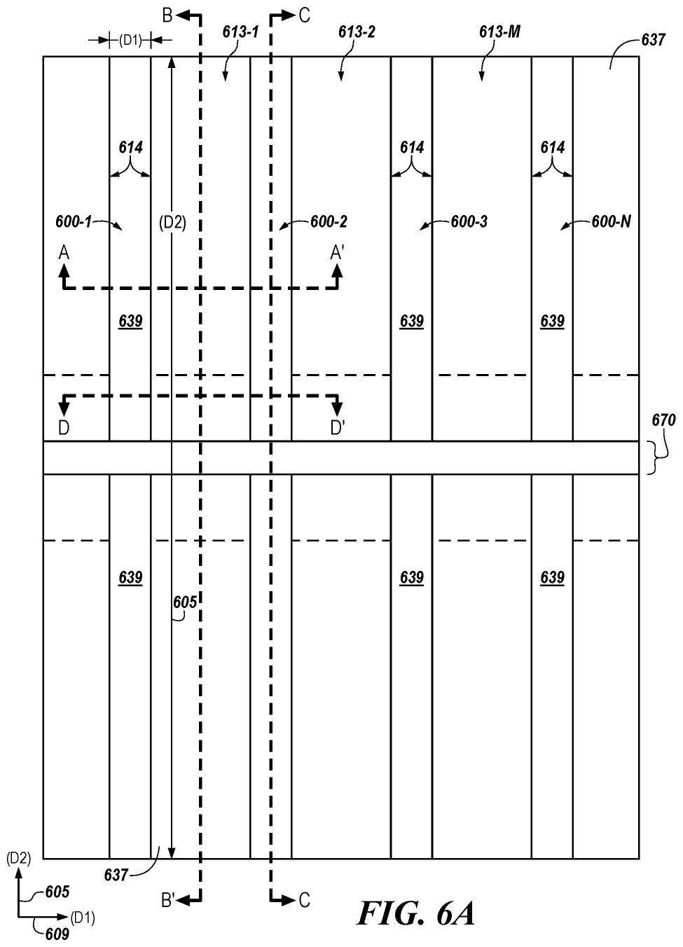

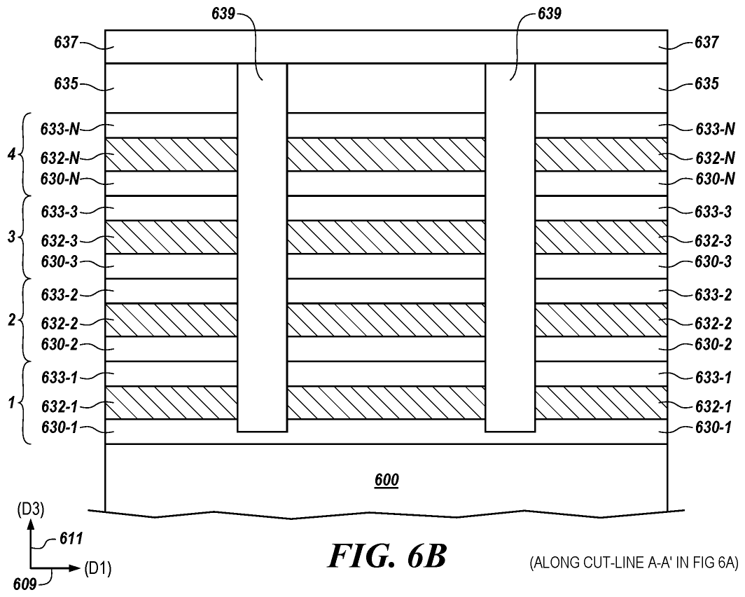

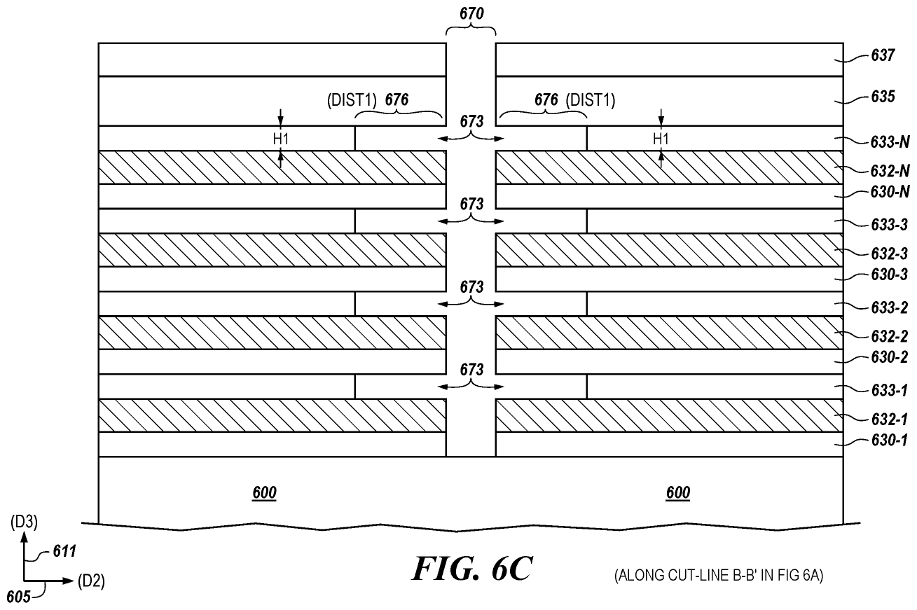

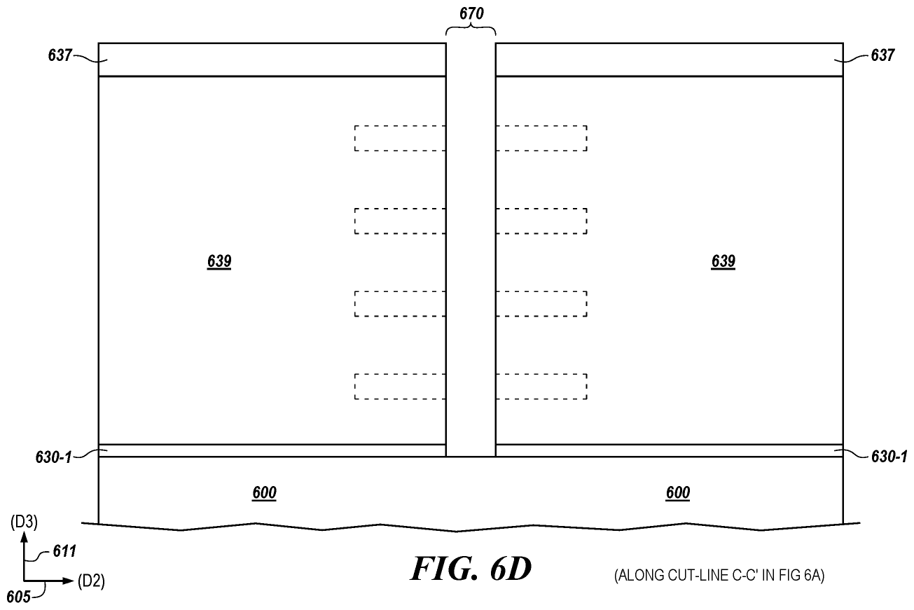

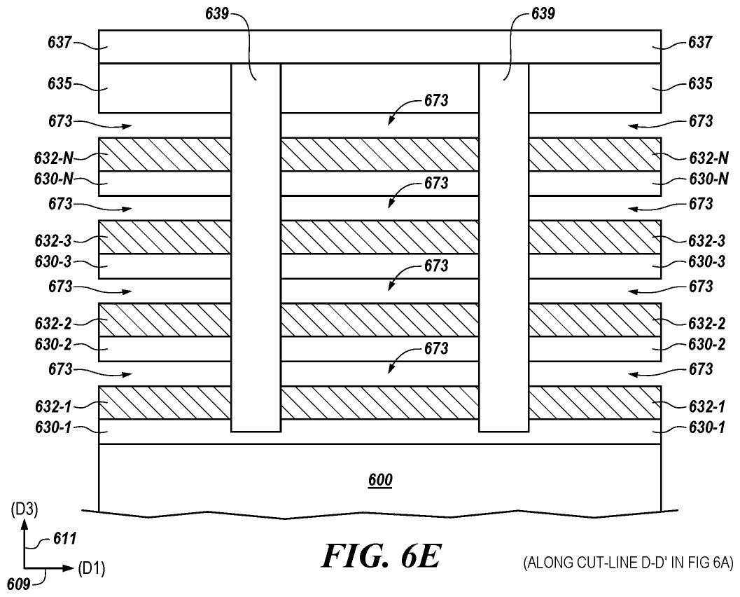

FIG. 6A illustrates an example method, at another stage of a semiconductor fabrication process, for forming arrays of vertically stacked memory cells, having a shared vertical digit line for semiconductor devices and horizontally oriented access lines, such as illustrated in FIGS. 1-3, and in accordance with a number of embodiments of the present disclosure. FIG. 6A illustrates a top down view of a semiconductor structure, at a particular point in time, in a semiconductor fabrication process, according to one or more embodiments. In the example embodiment shown in the example of FIG. 6A, a plurality of first vertical openings 600, having a first horizontal direction axis (D1) 609 and a second horizontal direction axis (D2) 605, have been formed through the vertical stack to the substrate. In one example, as shown in FIG. 6A, the plurality of first vertical openings 600 are extending predominantly in the second horizontal direction axis (D2) 605 and may form elongated vertical, pillar columns 613 with sidewalls 614 in the vertical stack.

In FIG. 6A, the method comprises using photolithographic techniques to pattern a mask and using an etchant process to form a continuous second opening 670, extending predominantly along the first horizontal direction axis (D1) 609, across the first vertical openings 600.

FIG. 6B is a cross sectional view, taken along cut-line A-A′ in FIG. 6A, showing another view of the semiconductor structure at this particular time in the semiconductor fabrication process. The cross sectional view shown in FIG. 6B shows the repeating iterations of alternating layers of a first dielectric material, 630-1, 630-2, . . . , 630-N, a first semiconductor material, 632-1, 632-2, . . . , 632-N, and a second dielectric material, 633-1, 633-2, . . . , 633-N, on a semiconductor substrate 600 to form the vertical stack, e.g. 401 as shown in FIG. 4.

As shown in FIG. 6B, a plurality of first vertical openings have been formed through the vertically stacked layers, in which will be formed vertically stacked memory cells, to expose vertical sidewalls in the vertical stack.

As shown in FIG. 6B, a third dielectric material 639, such as an oxide or other suitable spin on dielectric (SOD), has been deposited in the first vertical openings, using a process such as CVD, to fill the first vertical openings. A photolithographic material 637, e.g., hard mask, may be deposited using CVD and planarized using chemical mechanical planarization (CMP) to cover and close the first vertical openings over the vertical stack. Similar semiconductor process techniques may be used at other points of the semiconductor fabrication process described herein.

FIG. 6C is a cross-sectional view, at another stage of a semiconductor fabrication process, for forming shared vertical digit lines for semiconductor devices having horizontally oriented access devices and horizontally oriented access lines, such as illustrated in FIGS. 1-3, and in accordance with a number of embodiments of the present disclosure. FIG. 6C illustrates a cross sectional view, taken along cut-line B-B′ in FIG. 6A.

Continuous second vertical opening 670 may create an opening in the vertical stack, with a first portion of the vertical stack on one side of continuous second vertical opening 670 and a second portion of the vertical stack on a second, opposing side of continuous second vertical opening 670. The continuous second vertical opening 670 may extend predominantly in the first horizontal direction axis to expose second vertical sidewalls adjacent a first region of the first semiconductor material 632.

An etchant may be flowed into the second vertical opening 670 to selectively etch a portion of the second dielectric material 633 to form first horizontal openings 673 extending predominantly in the second horizontal direction axis (D2) 605. For example, an etchant may be flowed into the second vertical opening 670 to selectively etch the nitride material 633. The etchant may target all iterations of the second dielectric material 633 within the stack. As such, the etchant may target the first nitride material 633-1, the second nitride material 633-2, and the third nitride material 633-3 within the stack.

The selective etchant process may consist of one or more etch chemistries selected from an aqueous etch chemistry, a semi-aqueous etch chemistry, a vapor etch chemistry, or a plasma etch chemistries, among other possible selective etch chemistries. For example, a dry etch chemistry of oxygen (O₂) or O₂ and sulfur dioxide (SO₂) may be utilized. As another example, a dry etch chemistries of O₂ or of O₂ and nitrogen (N₂) may be used to selectively etch the second dielectric material 633. Alternatively, or in addition, a selective etch to remove the second dielectric material 633 may comprise a selective etch chemistry of phosphoric acid (H₃PO₄) and/or dissolving the second dielectric material 633 using a selective solvent.

The selective etchant process may etch the nitride material 633 to form a first horizontal opening 673. The selective etchant process may etch second dielectric material 633 in two opposing directions along the second horizontal direction axis 605 to form a plurality of first horizontal openings 673 in opposing directions and to form two adjacent horizontal access devices sharing vertically oriented digit lines with direct electric contact to formed first source/drain regions. The selective etchant process may be performed such that the first horizontal opening 673 has a length or depth (DIST 1) a first distance 676 from the second vertical opening 670. The first distance (DIST 1) 676 may be a further distance than used to form a first source/drain region. The second dielectric material 633 may be etched a first distance (DIST 1) 676 in a range of approximately fifty (50) to two hundred and fifty (250) nanometers (nm) back from the second vertical opening. The first distance (DIST 1) 676 may be controlled by controlling time, composition of etchant gas, and etch rate of a reactant gas flowed into the second vertical opening 670, e.g., rate, concentration, temperature, pressure, and time parameters. As such, the nitride material 633 may be etched a first distance 676 from the vertical opening. The selective etch may be isotropic, but selective to the second dielectric material 633, substantially stopping on the first dielectric material 630 and the first semiconductor material. Thus, in one example embodiment, the selective etchant process may remove substantially all of the nitride material 633 from a top surface of the first semiconductor material 632 to a bottom surface of the first dielectric material, e.g., oxide material, in a layer above while etching horizontally a first distance (DIST 1) 676 from the second vertical opening 670 adjacent a first region of the first semiconductor material 632. In this example, the horizontal opening 673 will have a height (H1) substantially equivalent to and be controlled by a thickness, to which the second dielectric layer 633, e.g., nitride material, was deposited. Embodiments, however, are not limited to this example. As described herein, the selective etchant process may etch the nitride material 633 to a first distance (DIST 1) 676 and to a height (H1).

FIG. 6D illustrates a cross sectional view, taken along cut-line C-C′ in FIG. 6A, showing another view of the semiconductor structure at this particular point in one example semiconductor fabrication process of an embodiment of the present disclosure. The cross sectional view shown in FIG. 6D is illustrated extending in the second horizontal direction axis (D2) 605, outside of a region for the horizontally oriented access devices and horizontally oriented storage nodes. Continuous second vertical opening 670 may be seen through the third dielectric material 639.

In FIG. 6E, the third dielectric material 639, such as an oxide or other suitable spin on dielectric (SOD), may be deposited in the first vertical openings, using a process such as CVD. The third dielectric material 639 is shown spaced along a first direction (D1), extending into and out from the plane of the drawings sheet, for a three dimensional array of vertically oriented memory cells. A hard mask 637, which may be deposited using CVD and planarized using chemical mechanical planarization (CMP), may be seen over the third dielectric material 639. Similar semiconductor process techniques may be used at other points of the semiconductor fabrication process described herein.

FIG. 6E illustrates a cross sectional view, taken along cut-line D-D′ in FIG. 6A, showing another view of the semiconductor structure at this particular point in one example semiconductor fabrication process of an embodiment of the present disclosure. The cross sectional view shown in FIG. 6E is illustrated, right to left in the plane of the drawing sheet, extending in the first direction (D1) 609 along an axis of the repeating iterations of alternating layers of a first dielectric material, 630-1, 630-2, . . . , 630-N and a first semiconductor material, 632-1, 632-2, . . . , 632-N, intersecting across the plurality of third dielectric fill material 639.

In this cross sectional view, the etched second dielectric material 633-1, 633-2, . . . , 633-N may be seen such that the second dielectric material 633-1, 633-2, . . . , 633-N may seem completely removed by selective etching to form first horizontal opening 673. In FIG. 6E, the third dielectric fill material 639 is shown separating the space between the first horizontal openings 673, which can be spaced along a first direction (D1) 609 and stacked vertically in arrays extending in the third direction (D3) 611 in the three dimensional (3D) memory. A hard mask 637, may be deposited using CVD and planarized using chemical mechanical planarization (CMP) to cover and close the first vertical openings over the vertical stack.

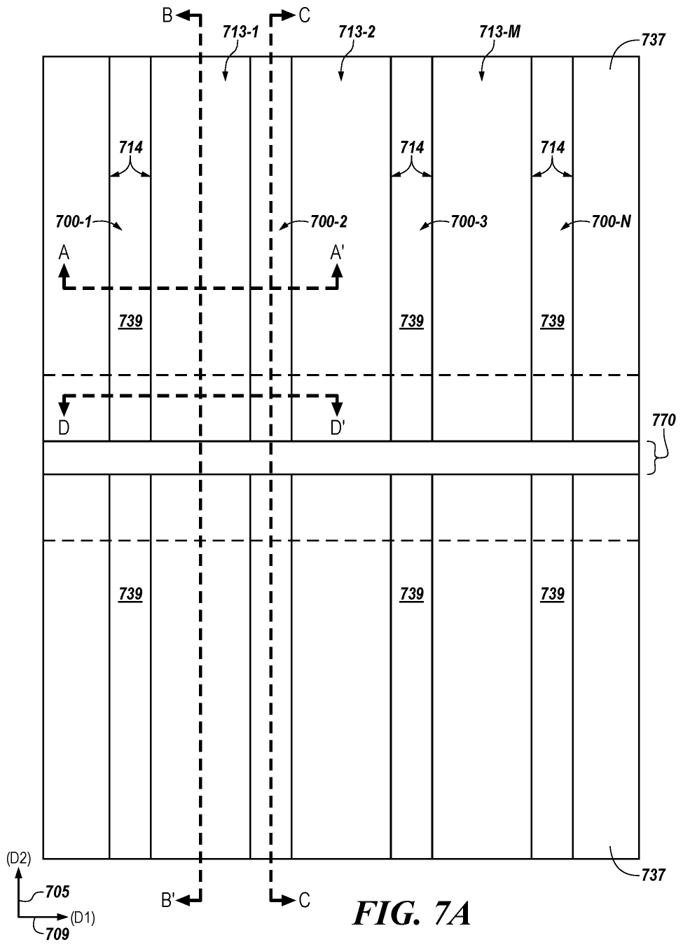

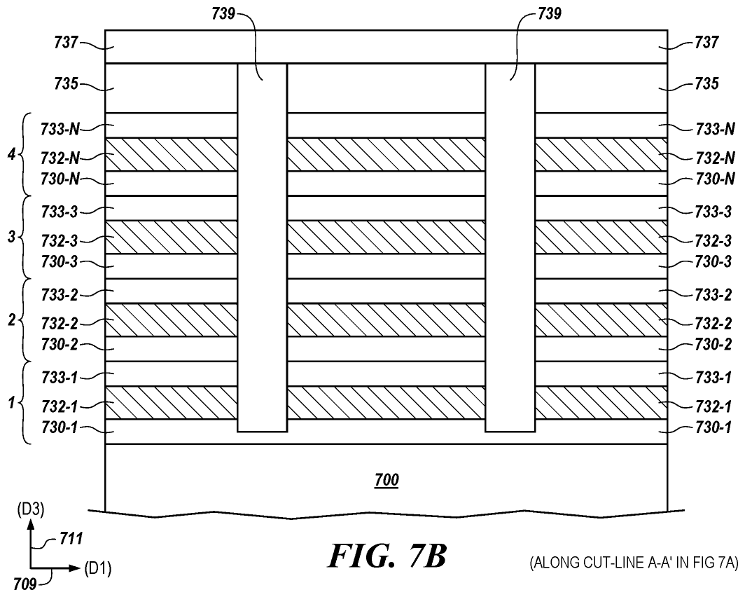

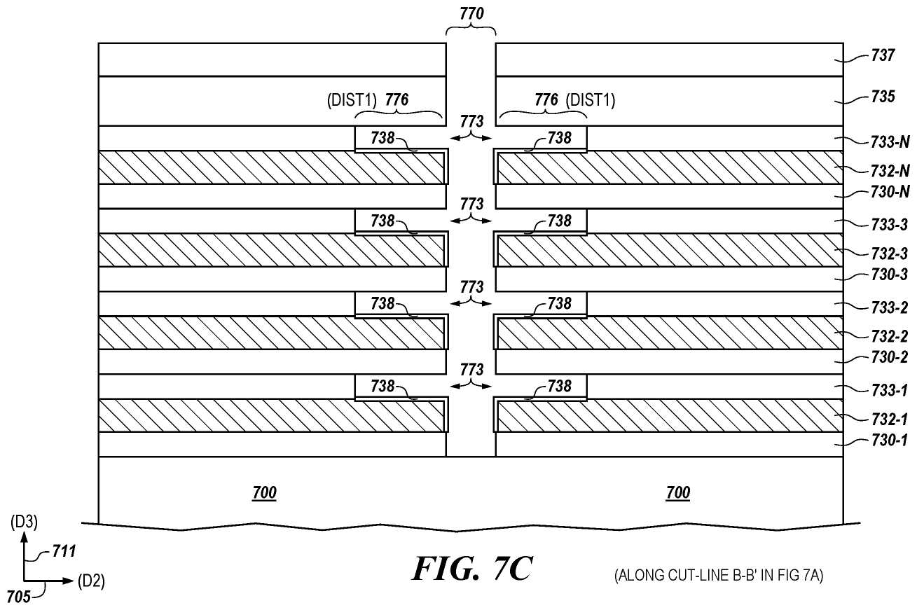

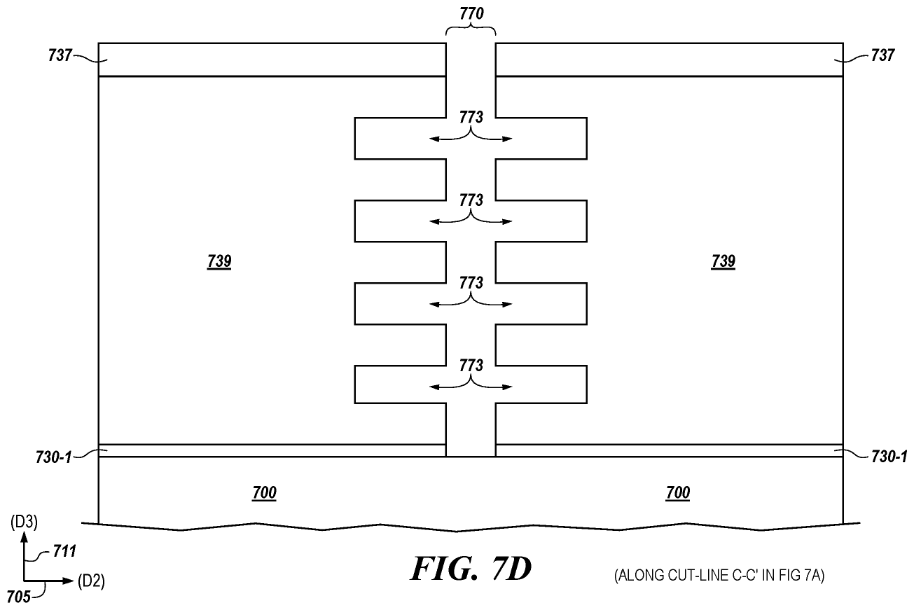

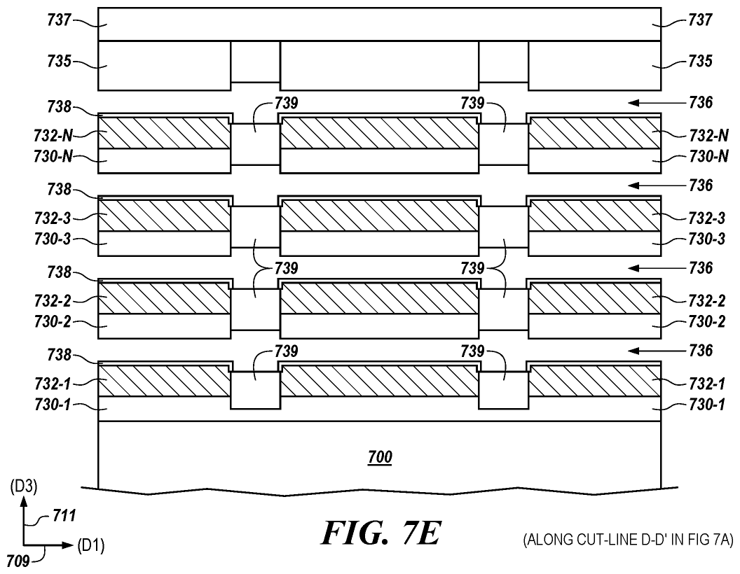

FIG. 7A illustrates an example method, at another stage of a semiconductor fabrication process, for forming arrays of vertically stacked memory cells, having a shared vertical digit line for semiconductor devices and horizontally oriented access lines, such as illustrated in FIGS. 1-3, and in accordance with a number of embodiments of the present disclosure. FIG. 7A illustrates a top down view of a semiconductor structure, at a particular point in time, in a semiconductor fabrication process, according to one or more embodiments. In the example embodiment shown in FIG. 7A, the method comprises using an etchant process to etch through the third dielectric material 739 that filled in the plurality of first vertical openings 700, having a first horizontal direction axis (D1) 709 and a second horizontal direction axis (D2) 705, through the vertical stack to the substrate. The plurality of first vertical openings 700 and continuous second opening 770 may be viewed within the hard mask 737 within the working surface of the vertical semiconductor stack. The third dielectric material 739 may be etched to a height within the hard mask 737.

FIG. 7B is a cross sectional view, taken along cut-line A-A′ in FIG. 7A, showing another view of the semiconductor structure at a particular time in the semiconductor fabrication process. The cross sectional view shown in FIG. 7B shows the repeating iterations of alternating layers of a first dielectric material, 730-1, 730-2, . . . , 730-N, a first semiconductor material, 732-1, 732-2, . . . , 732-N, and a second dielectric material, 733-1, 733-2, . . . , 733-N, on a semiconductor substrate 700.

As shown in FIG. 7B, a plurality of first vertical openings may be formed through the layers within the vertically stacked memory cells to expose vertical sidewalls in the vertical stack. The first vertical openings may be formed through the repeating iterations of the oxide material 730, the first semiconductor material 732, and the nitride material 733. As such, the first vertical openings may be formed through the first oxide material 730-1, the first semiconductor material 732-1, the first nitride material 733-1, the second oxide material 730-2, the second semiconductor material 732-2, the second nitride material 733-2, the third oxide material 730-3, the third semiconductor material 732-3, and the third nitride material 733-3. Embodiments, however, are not limited to the vertical opening(s) shown in FIG. 7B. Multiple vertical openings may be formed through the layers of materials. The first vertical openings may be formed to expose vertical sidewalls in the vertical stack. The first vertical openings may extend in a second horizontal direction axis (D2) 705 to form elongated vertical, pillar columns with first vertical sidewalls in the vertical stack.

As shown in FIG. 7B, a third dielectric material 739, such as an oxide or other suitable spin on dielectric (SOD), may be viewed in the first vertical openings, filling the first vertical openings. A hard mask 737 may be deposited to cover and close the first vertical openings over the vertical stack. Similar semiconductor process techniques may be used at other points of the semiconductor fabrication process described herein.

FIG. 7C is a cross-sectional view, at another stage of a semiconductor fabrication process, for forming shared vertical digit lines for semiconductor devices having horizontally oriented access devices and horizontally oriented access lines, such as illustrated in FIGS. 1-3, and in accordance with a number of embodiments of the present disclosure. FIG. 7C illustrates a cross sectional view, taken along cut-line B-B′ in FIG. 7A.

The second dielectric material 733 may be selectively etched in the second horizontal direction axis (D2) 705 to form a plurality of first horizontal openings 773. An etchant may be flowed into the second vertical opening 770 to selectively etch a portion of the second dielectric material 733. As such, the etchant may target the first nitride material 733-1, the second nitride material 733-2, and the third nitride material 733-3 within the stack. The selective etchant process may etch the nitride material 733 to form a first horizontal opening 773. The selective etchant process may etch the nitride material 733 to a first distance (DIST 1) 776 and to a height (H1).

As shown in FIG. 7C, another etchant may be flowed into the second vertical opening 770 to punch through third dielectric material 739 with a lateral exhume to form continuous second horizontal openings extending in the first horizontal direction axis (D1) 709. The etchant may be selective only to third dielectric material 739 and may not etch first dielectric material 730. As such, spin-on dielectric 739 may be formed from a different material from oxide material 730.

A gate dielectric material 738 may be deposited in the plurality of first horizontal openings 773 created by the etched second dielectric material 733. The gate dielectric material 738 may be conformally deposited on the first semiconductor material 732. A gate dielectric material 738 may be conformally deposited in the plurality of first horizontal openings 773 using a chemical vapor deposition (CVD) process, plasma enhanced CVD (PECVD), atomic layer deposition (ALD), or other suitable deposition process, to cover a bottom surface and the vertical sidewalls of the plurality of first horizontal openings 773. In another embodiment, gate dielectric material 738 may be thermally grown onto a surface of first semiconductor material 732. By way of example, and not by way of limitation, the gate dielectric 738 may comprise a silicon dioxide (SiO2) material, aluminum oxide (Al₂O₃) material, high dielectric constant (k), e.g., high-k, dielectric material, and/or combinations thereof.

FIG. 7D illustrates a cross sectional view, taken along cut-line C-C′ in FIG. 7A, showing another view of the semiconductor structure at this particular point in one example semiconductor fabrication process of an embodiment of the present disclosure. The cross sectional view shown in FIG. 7D is illustrated extending in the second horizontal direction axis (D2) 705, outside of a region for the horizontally oriented access devices and horizontally oriented storage nodes.

In FIG. 7D, the third dielectric material 739 is shown filling the space along a first direction (D1), extending into and out from the plane of the drawings sheet, for a three dimensional array of vertically oriented memory cells. A portion of the third dielectric material 739 may be etched in a horizontal direction to view repeating iterations of alternating layers of a first dielectric material, 730-1, 730-2, . . . , 730-N and a first semiconductor material, 732-1, 732-2, . . . , 732-N. A lateral punch may be applied to the dielectric material 739 to etch through. An etchant, selective only to third dielectric material 739 may be flowed into the second vertical opening 770 to punch through third dielectric material 739. The hard mask 737 may be viewed over third dielectric material 739.

FIG. 7E illustrates a cross sectional view, taken along cut-line D-D′ in FIG. 7A, showing another view of the semiconductor structure at this particular point in one example semiconductor fabrication process of an embodiment of the present disclosure. The cross sectional view shown in FIG. 7E is illustrated, right to left in the plane of the drawing sheet, extending in the first direction (D1) 709 along an axis of the repeating iterations of alternating layers of a first dielectric material, 730-1, 730-2, . . . , 730-N and a first semiconductor material, 732-1, 732-2, . . . , 732-N, intersecting across the plurality of third dielectric fill material 739.

In FIG. 7E, the third dielectric fill material 739 is shown separating the space between the first horizontal openings 773, and can be spaced along a first direction (D1) 709 and stacked vertically in arrays extending in the third direction (D3) 711 in the three dimensional (3D) memory. A portion of the third dielectric material 739 may be etched vertically. A portion of the third dielectric fill 739 within the plurality of first vertical openings may be removed. The openings created by the etched third dielectric material 739 may form continuous second horizontal openings 779 that extend in the first horizontal direction axis 709. A hard mask 737, covering the first vertical openings over the vertical stack may be etched in the same manner as the third dielectric material 739.

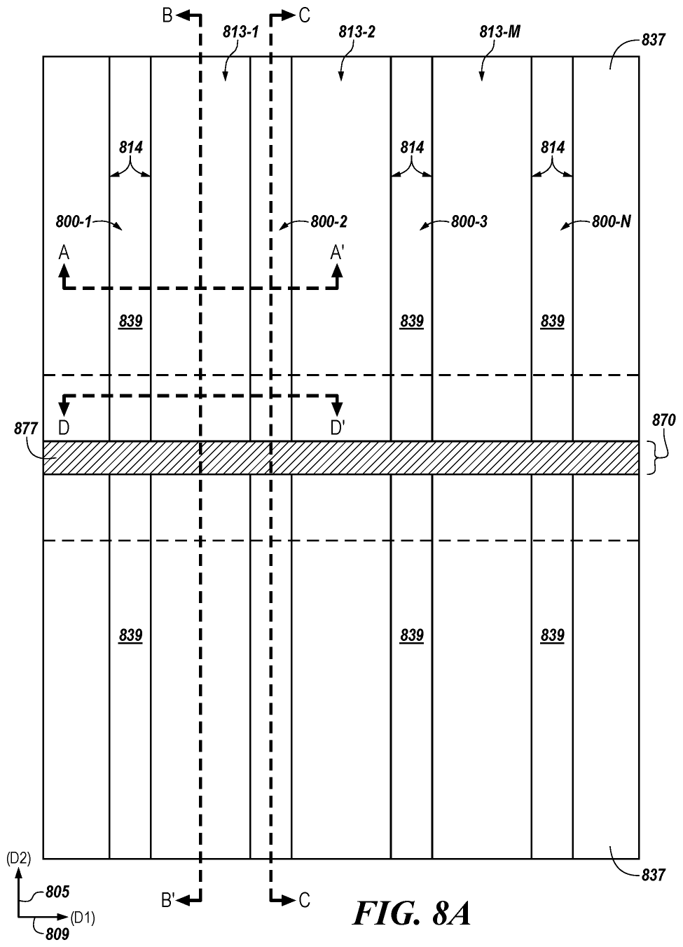

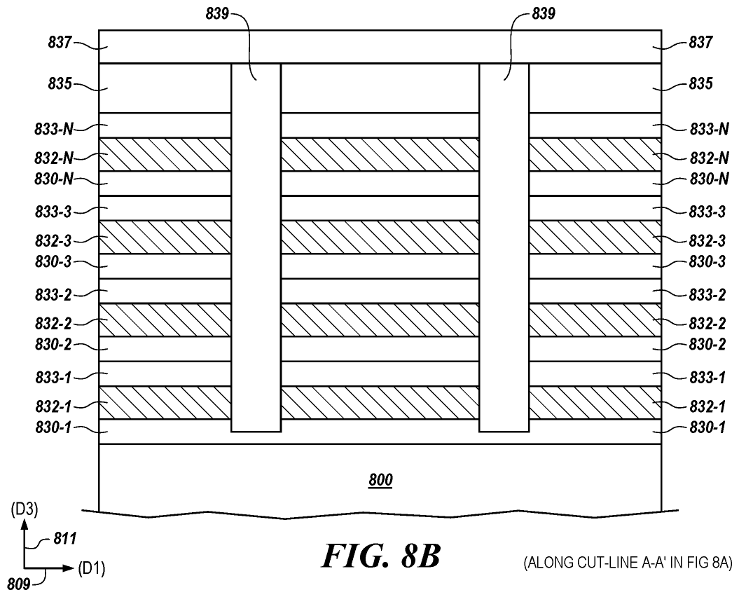

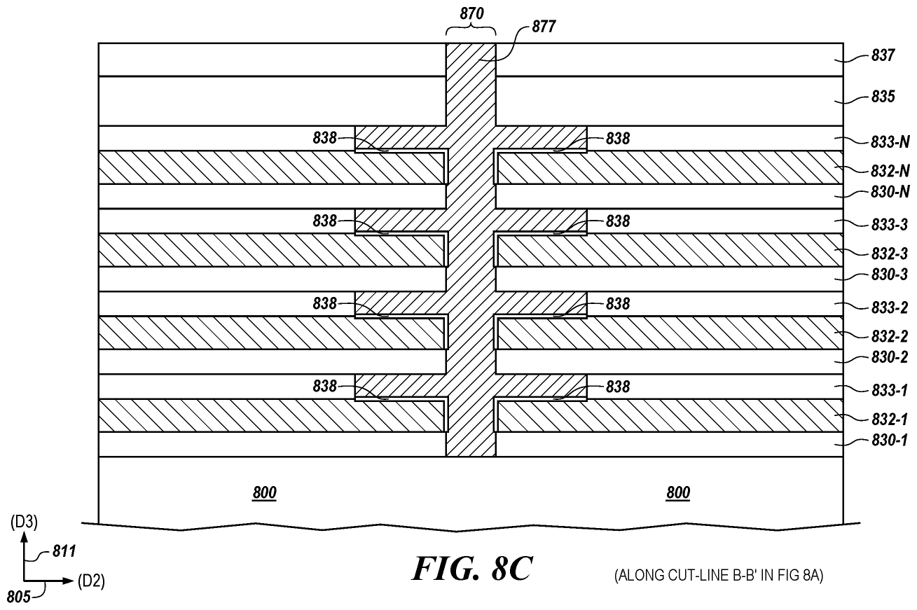

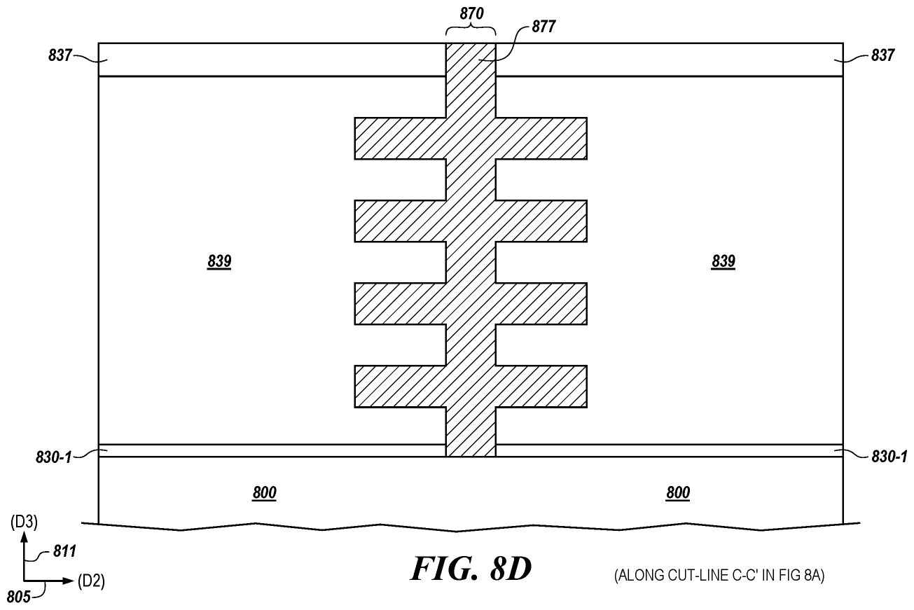

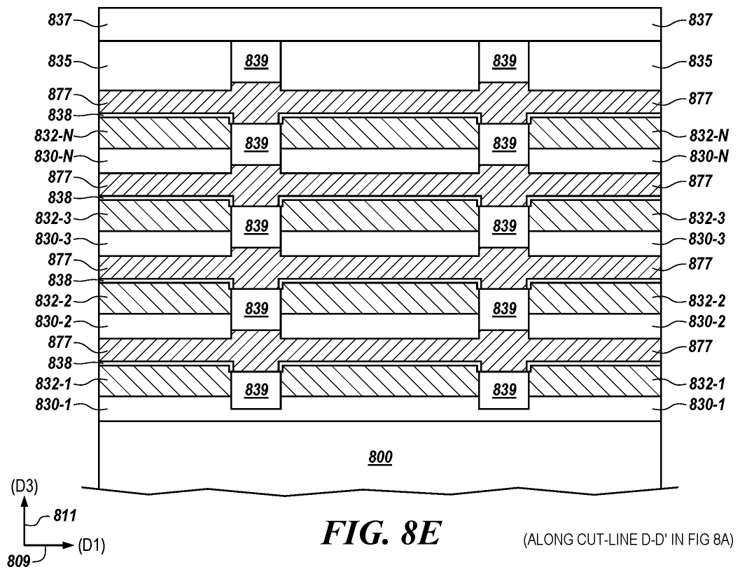

FIG. 8A illustrates an example method, at another stage of a semiconductor fabrication process, for forming arrays of vertically stacked memory cells, having a shared vertical digit line for semiconductor devices and horizontally oriented access lines, such as illustrated in FIGS. 1-3, and in accordance with a number of embodiments of the present disclosure. FIG. 8A illustrates a top down view of a semiconductor structure, at a particular point in time, in a semiconductor fabrication process, according to one or more embodiments. In the example embodiment shown in FIG. 8A, the method comprises filling continuous second opening 870 having a horizontal direction (D2) 805. A conductive gate material 877 may be deposited within continuous second opening 870.

FIG. 8B is a cross sectional view, taken along cut-line A-A′ in FIG. 8A, showing another view of the semiconductor structure at a particular time in the semiconductor fabrication process. The cross sectional view shown in FIG. 8B shows the repeating iterations of alternating layers of a first dielectric material, 830-1, 830-2, . . . , 830-N, a first semiconductor material, 832-1, 832-2, . . . , 832-N, and a second dielectric material, 833-1, 833-2, . . . , 833-N, on a semiconductor substrate 800.

As shown in FIG. 8B, a plurality of first vertical openings have been formed through the layers within the vertically stacked memory cells to expose vertical sidewalls in the vertical stack. The first vertical openings have been filled with third dielectric material 839. The first vertical openings have been formed through the repeating iterations of the oxide material 830, the first semiconductor material 832, and the nitride material 833.

FIG. 8C is a cross-sectional view, at another stage of a semiconductor fabrication process, for forming shared vertical digit lines for semiconductor devices having horizontally oriented access devices and horizontally oriented access lines, such as illustrated in FIGS. 1-3, and in accordance with a number of embodiments of the present disclosure. FIG. 8C illustrates a cross sectional view, taken along cut-line B-B′ in FIG. 8A.

A conductive gate material, 877-1, 877-2, . . . , 877-N (collectively referred to as conductive gate material 877), may be conformally deposited and fill the second vertical opening 870, using a chemical vapor deposition (CVD) process, plasma enhanced CVD (PECVD), atomic layer deposition (ALD), or other suitable deposition process, such that the conductive gate material 877 may also be deposited into the first horizontal openings (736 in FIG. 7E) extending predominantly in the second horizontal axis direction (D2) 805, and into the continuous second horizontal openings (773 in FIG. 7C) extending predominantly in the first horizontal directions axis (D1) 809. The conductive gate material 877 may be deposited on the gate dielectric material 838.

In some embodiments, the conductive gate material, 877-1, 877-2, . . . , 877-N, may comprise one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc, and/or some other combination thereof as also described in FIG. 3. The conductive gate material 877 formed on the gate dielectric material 838 may form horizontally oriented access lines, such as shown as access lines 103-1, 103-2, . . . , 103-Q (which also may be referred to as wordlines).

FIG. 8D illustrates a cross sectional view, taken along cut-line C-C′ in FIG. 8A, showing another view of the semiconductor structure at this particular point in one example semiconductor fabrication process of an embodiment of the present disclosure. The cross sectional view shown in FIG. 8D is illustrated extending in the second horizontal direction axis (D2) 805, outside of a region for the horizontally oriented access devices and horizontally oriented storage nodes.

In FIG. 8D, the third dielectric material 839 is shown filling the space along a first direction (D1), extending into and out from the plane of the drawings sheet, for a three dimensional array of vertically oriented memory cells. The cross sectional view shown in FIG. 8D is illustrated, right to left in the plane of the drawing sheet, extending in the second horizontal direction axis (D2) 805. The second continuous vertical opening 870 may be seen intersecting the third dielectric material 839. The conductive gate material, 877-1, 877-2, . . . , 877-N, may fill the second vertical opening 870, the continuous second horizontal openings extending predominantly in the first horizontal direction axis (D1) 809 (punched through the third dielectric material 839) and the first horizontal openings extending predominantly along the second horizontal direction axis (D2) 805. The conductive gate material, 877-1, 877-2, . . . , 877-N, may be conformally deposited using a chemical vapor deposition (CVD) process, plasma enhanced CVD (PECVD), atomic layer deposition (ALD), or other suitable deposition process.

The hard mask 837, may be viewed over third dielectric material 839. The conductive gate material, 877-1, 877-2, . . . , 877-N, within second continuous vertical opening 870 may intersect hard mask 837.

FIG. 8E illustrates a cross sectional view, taken along cut-line D-D′ in FIG. 8A, showing another view of the semiconductor structure at this particular point in one example semiconductor fabrication process of an embodiment of the present disclosure. The cross sectional view shown in FIG. 8E is illustrated, right to left in the plane of the drawing sheet, extending in the first direction (D1) 809 along an axis of the repeating iterations of alternating layers of a conductive gate material, 877-1, 877-2, . . . , 877-N formed on a gate dielectric material 838, a first dielectric material, 830-1, 830-2, . . . , 830-N, and a first semiconductor material, 832-1, 832-2, . . . , 832-N, intersecting across the plurality of third dielectric fill material 839.

In FIG. 8E, the conductive gate material, 877-1, 877-2, . . . , 877-N, is shown filling in the space in the second vertical opening 870 left by the etched portion of the second dielectric (illustrated as 533 in FIGS. 5). Third dielectric fill material 839 is shown spaced along a first direction (D1) 809 and stacked vertically in arrays extending in the third direction (D3) 811 in the three dimensional (3D) memory. The conductive gate material, 877-1, 877-2, . . . , 877-N, formed on a gate dielectric material 838, may fill the openings created by the etched second dielectric material 833. A hard mask 837, covering the first vertical openings over the vertical stack may be etched in the same manner as the third dielectric material 839. conductive gate material

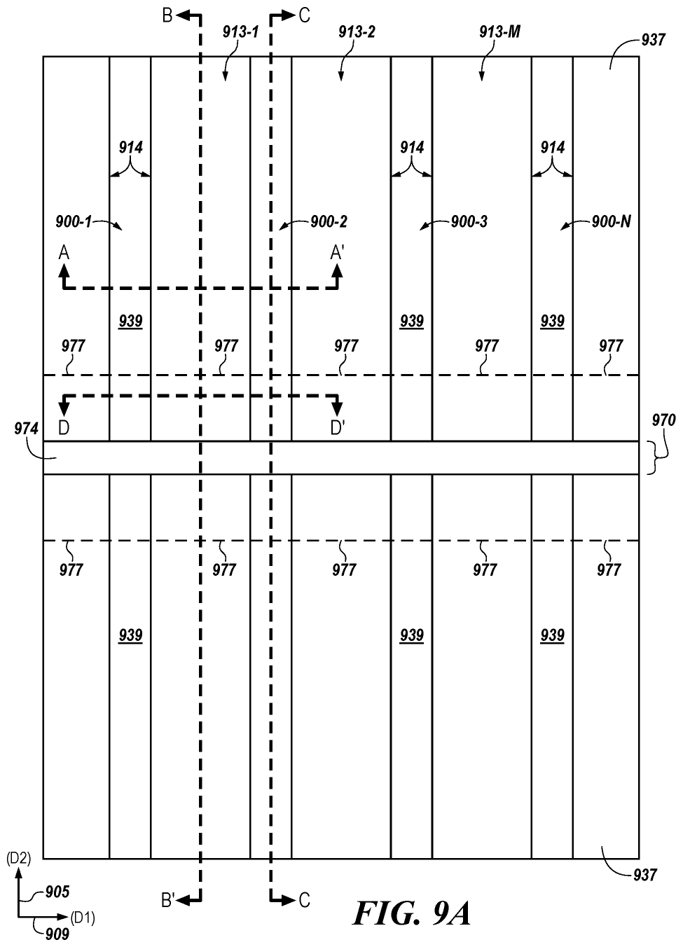

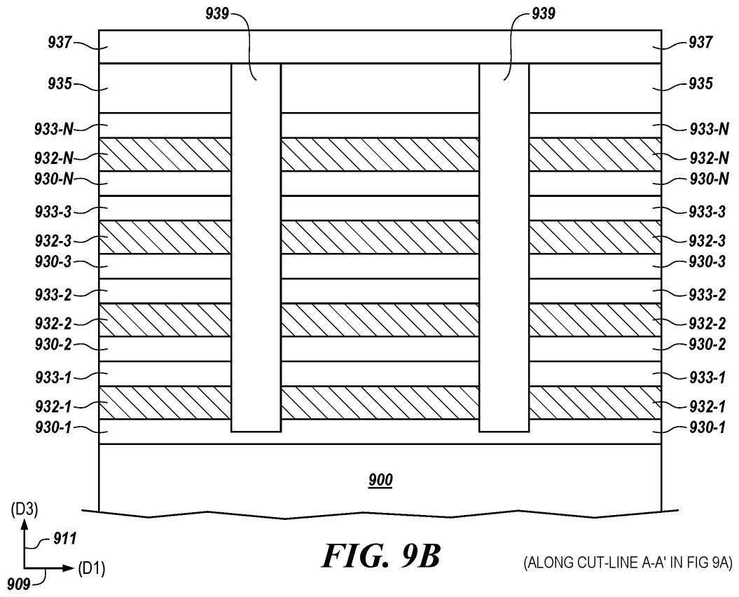

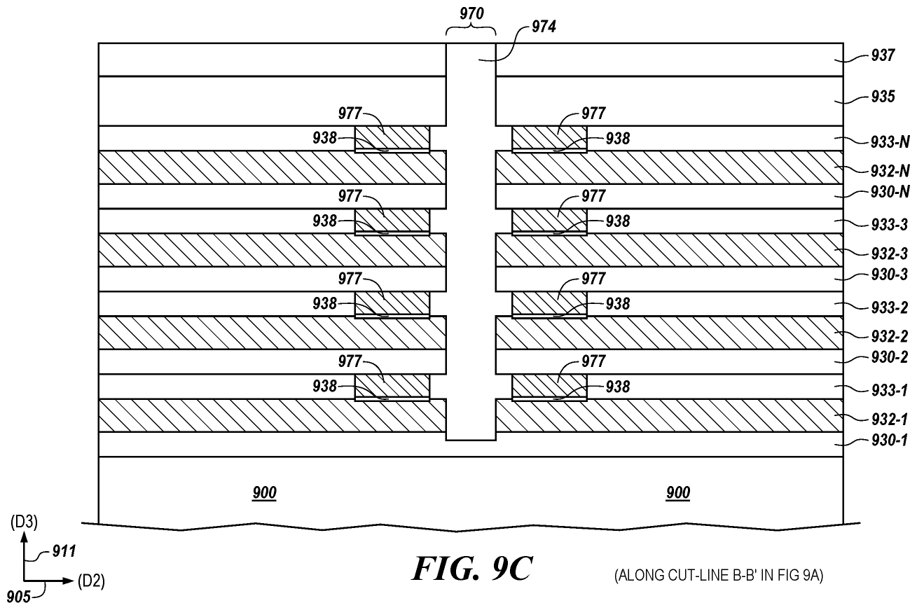

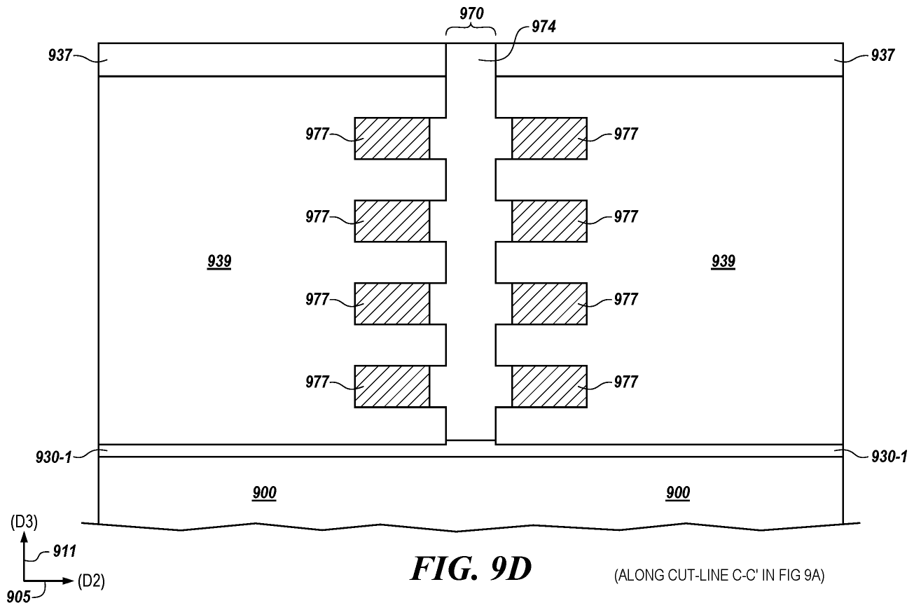

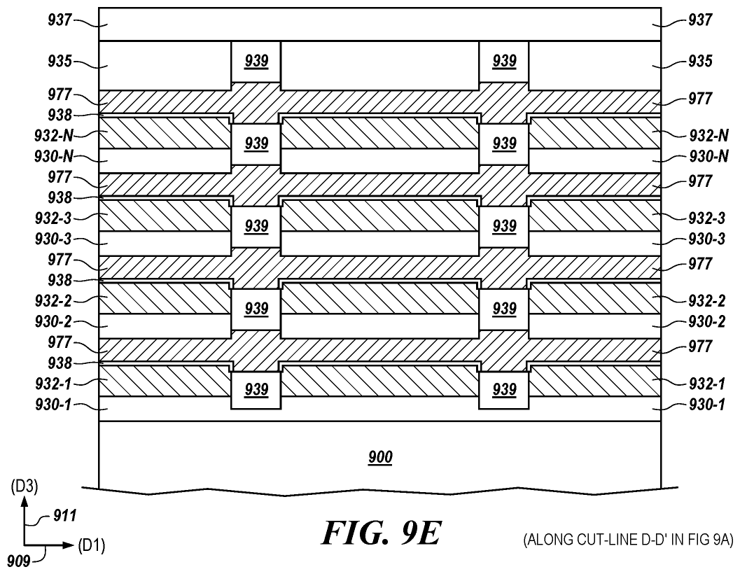

FIG. 9A illustrates an example method, at another stage of a semiconductor fabrication process, for forming arrays of vertically stacked memory cells, having a shared vertical digit line for semiconductor devices and horizontally oriented access lines, such as illustrated in FIGS. 1-3, and in accordance with a number of embodiments of the present disclosure. FIG. 9A illustrates a top down view of a semiconductor structure, at a particular point in time, in a semiconductor fabrication process, according to one or more embodiments. In the example embodiment shown in FIG. 9A, the method comprises using an etchant process to etch through the conductive gate material, 977-1, 977-2, . . . , 977-N, that was formed within the second continuous vertical opening 970, having a first horizontal direction axis (D1) 909.

A fourth dielectric material 974 may fill spaces left between the etched conductive gate material 977 and second continuous vertical opening 970. For example, dielectric material 974 may fill the first horizontal opening (illustrated by 773 in FIG. 7). A fourth dielectric material 974, such as an oxide or other suitable spin on dielectric (SOD), may be deposited in the second continuous vertical opening 970, to fill spaces between the etched conductive gate material 977 and second continuous vertical opening 970. The fourth dielectric material 974, may be deposited using CVD and planarized using chemical mechanical planarization (CMP) to cover and close the first horizontal opening. Similar semiconductor process techniques may be used at other points of the semiconductor fabrication process described herein.

FIG. 9B is a cross sectional view, taken along cut-line A-A′ in FIG. 9A, showing another view of the semiconductor structure at a particular time in the semiconductor fabrication process. The cross sectional view shown in FIG. 9B shows the repeating iterations of alternating layers of a first dielectric material, 930-1, 930-2, . . . , 930-N, a first semiconductor material, 932-1, 932-2, . . . , 932-N, and a second dielectric material, 933-1, 933-2, . . . , 933-N, on a semiconductor substrate 900.

FIG. 9C is a cross-sectional view, at another stage of a semiconductor fabrication process, for forming shared vertical digit lines for semiconductor devices having horizontally oriented access devices and horizontally oriented access lines, such as illustrated in FIGS. 1-3, and in accordance with a number of embodiments of the present disclosure. FIG. 9C illustrates a cross sectional view, taken along cut-line B-B′ in FIG. 9A.

The conductive gate material, 977-1, 977-2, . . . , 977-N, may be recessed back in the first horizontal opening, e.g., etched away from the second vertical opening 970 using an atomic layer etching (ALE) or other suitable technique before the fourth dielectric material is deposited. In some examples, the conductive gate material 977 may be etched back in the horizontal opening. The conductive gate material 977 may be etched back in the horizontal opening a second distance (DIST 2) 983 for a range of twenty (20) to one hundred and fifty (150) nanometers (nm) back from the second vertical opening 970. The conductive gate material 877 may be selectively etched, leaving the oxide material 930, a portion of the conductive gate material 977, and the first semiconductor material 932 intact. In some embodiments, the conductive gate material 977 may be etched using an atomic layer etching (ALE) process. In some embodiments, the conductive gate material 977 may be etched using an isotropic etch process. conductive gate material

The conductive gate material 977 may be recessed the second distance (DIST 2) 983 back in the first horizontal opening to remain in direct contact with the remaining portion of the nitride material 933 and on a top surface of the first semiconductor material 932. As such, the conductive gate material 977 formed on the gate dielectric material 938 may form horizontally oriented access lines.

A fourth dielectric material 974 may then be deposited to fill the first horizontal opening. For example, dielectric material 974 may fill spaces left between the etched conductive gate material 977 and second continuous vertical opening 970. In some embodiments, the fourth dielectric material 974 may be below the first dielectric material 930, above the low doped first semiconductor material 932. The fourth dielectric material 974 may be in direct contact with the conductive gate material 977 and the low doped first semiconductor material 932. Embodiments, however, are not limited to this example. A fourth dielectric material 974, such as an oxide or other suitable spin on dielectric (SOD), may be deposited in the second continuous vertical opening 970. The fourth dielectric material 974 may be the same material or a different material as the second dielectric material 33. For example, the second dielectric material 1033 may be Si3N4 and the fourth dielectric material 974 may also be Si₃N₄. In another example, the fourth dielectric material 974 may comprise a silicon dioxide (SiO₂) material. In another example, the fourth dielectric material 974 may comprise a silicon oxy-carbide (SiOₓC_{y}) material. In another example, the fourth dielectric material 1074 may include silicon oxy-nitride (SOₓN_{y}), and/or combinations thereof. Embodiments are not limited to these examples.

The fourth dielectric material 974, may be deposited using chemical vapor deposition (CVD) process, plasma enhanced CVD (PECVD), atomic layer deposition (ALD), or other suitable deposition process to cover and close the first horizontal opening. Similar semiconductor process techniques may be used at other points of the semiconductor fabrication process described herein.

FIG. 9D illustrates a cross sectional view, taken along cut-line C-C′ in FIG. 9A, showing another view of the semiconductor structure at this particular point in one example semiconductor fabrication process of an embodiment of the present disclosure. The cross sectional view shown in FIG. 9D is illustrated extending in the second horizontal direction axis (D2) 905, outside of a region for the horizontally oriented access devices and horizontally oriented storage nodes.

In FIG. 9D, the third dielectric material 939 is shown filling the space along a first direction (D1), extending into and out from the plane of the drawings sheet, for a three dimensional array of vertically oriented memory cells. The cross sectional view shown in FIG. 9D is illustrated, right to left in the plane of the drawing sheet, extending in the second horizontal direction axis (D2) 905 along an axis of the repeating iterations of alternating layers of an etched portion of the conductive gate material, 977-1, 977-2, . . . , 977-N. The conductive gate material, 977-1, 977-2, . . . , 977-N, may fill the openings created by the etched second dielectric material 933. The conductive gate material, 977-1, 977-2, . . . , 977-N, may be recessed back in the first horizontal opening, e.g., etched away from the second vertical opening 970. Fourth dielectric material 974 may fill the second continuous vertical opening 970 and the spaces created by the recessed conductive gate material 977 within the first horizontal openings and the continuous second horizontal openings. The hard mask 937, may be viewed over third dielectric material 939. conductive gate material

FIG. 9E illustrates a cross sectional view, taken along cut-line D-D′ in FIG. 9A, showing another view of the semiconductor structure at this particular point in one example semiconductor fabrication process of an embodiment of the present disclosure. The cross sectional view shown in FIG. 9E is illustrated, right to left in the plane of the drawing sheet, extending in the first direction (D1) 809 along an axis of the repeating iterations of alternating layers of a conductive gate material, 977-1, 977-2, . . . , 977-N formed on a gate dielectric material 938, a first dielectric material, 930-1, 930-2, . . . , 930-N, and a first semiconductor material, 932-1, 932-2, . . . , 932-N, intersecting across the plurality of third dielectric fill material 939.

In FIG. 9E, the conductive gate material, 977-1, 977-2, . . . , 977-N, is shown filling in the space in the continuous second horizontal openings punched through the third dielectric material 939 and left open by the etched portion of the second dielectric. Third dielectric fill material 939 is shown spaced along a first direction (D1) 909 and stacked vertically in arrays extending in the third direction (D3) 911 in the three dimensional (3D) memory. The conductive gate material, 977-1, 977-2, . . . , 977-N, may fill the openings created by the etched second dielectric material 933.

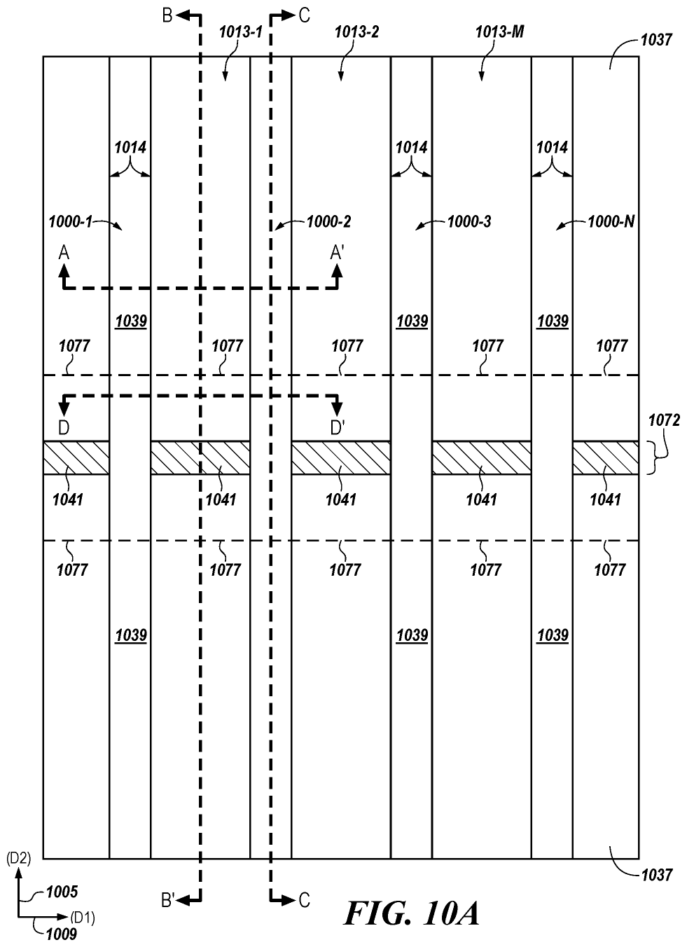

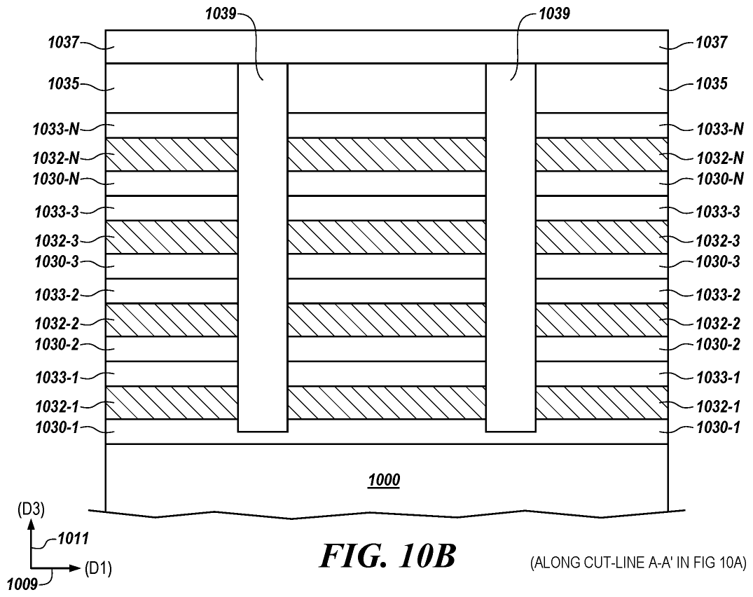

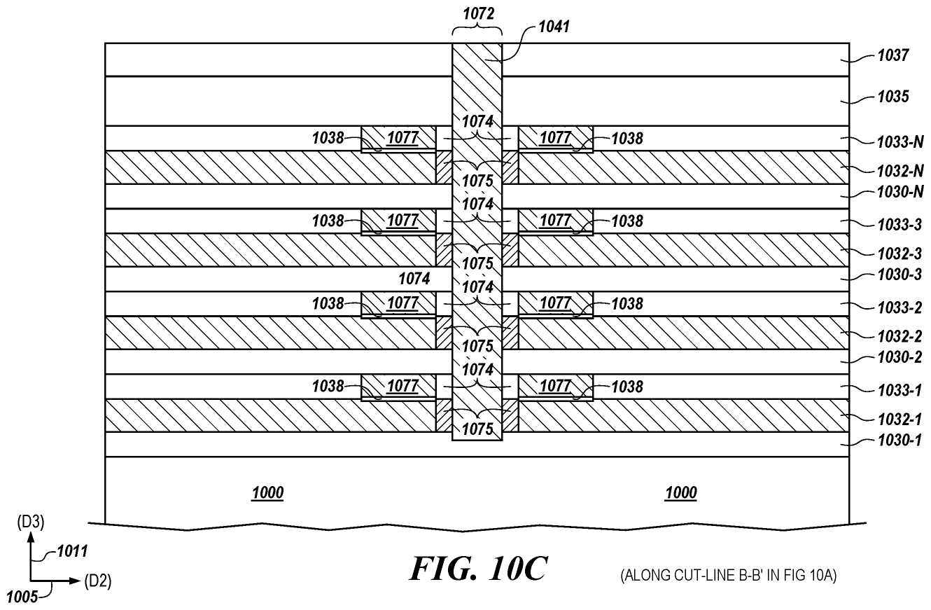

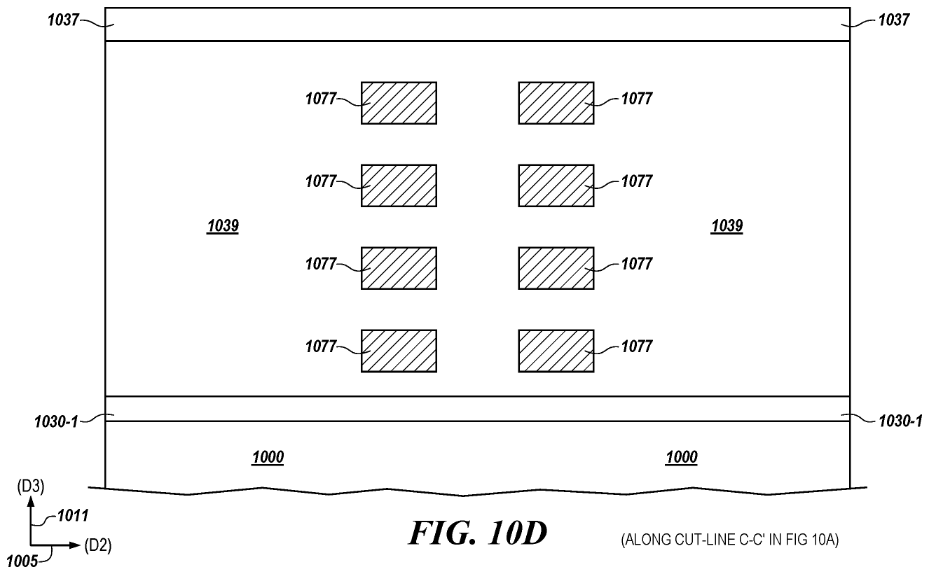

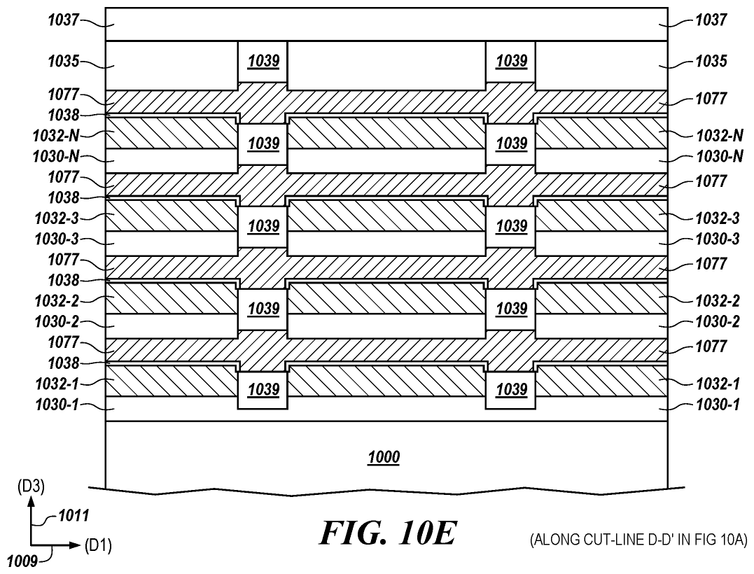

FIG. 10A illustrates an example method, at another stage of a semiconductor fabrication process, for forming arrays of vertically stacked memory cells, having a shared vertical digit line for semiconductor devices and horizontally oriented access lines, such as illustrated in FIGS. 1-3, and in accordance with a number of embodiments of the present disclosure to form a shared vertical digit line, e.g., 103 in FIG. 1. FIG. 10A illustrates a top down view of a semiconductor structure, at a particular point in time, in a semiconductor fabrication process, according to one or more embodiments. In the example embodiment shown in FIG. 10A, the method comprises forming a plurality of third vertical openings 1072 to deposit a second semiconductive material 1041. The third vertical openings 1072, having a first horizontal direction axis (D1) 1009, is not continuous and does not intersect third dielectric material 1039. The third dielectric material 1039 formed within plurality of first vertical openings 1000 may be viewed separating the working surface of the vertical semiconductor stack.

FIG. 10B is a cross sectional view, taken along cut-line A-A′ in FIG. 10A, showing another view of the semiconductor structure at a particular time in the semiconductor fabrication process. The cross sectional view shown in FIG. 10B shows the repeating iterations of alternating layers of a first dielectric material, 1030-1, 1030-2, . . . , 1030-N, a first semiconductor material, 1032-1, 1032-2, . . . , 1032-N, and a second dielectric material, 1033-1, 1033-2, . . . , 1033-N, on a semiconductor substrate 1000 in a storage node region.

As shown in FIG. 10B, a plurality of first vertical openings have been formed through the layers within the vertically stacked memory cells to expose vertical sidewalls in the vertical stack. The first vertical openings have been formed through the repeating iterations of the oxide material 1030, the first semiconductor material 1032, and the nitride material 1033.

FIG. 10C is a cross-sectional view, at another stage of a semiconductor fabrication process, for forming vertical digit lines for semiconductor devices having horizontally oriented access devices and horizontally oriented access lines, such as illustrated in FIGS. 1-3, and in accordance with a number of embodiments of the present disclosure. FIG. 10C illustrates a cross sectional view, taken along cut-line B-B′ in FIG. 10A.

Conductive gate material 1077 is illustrated adjacent the second dielectric material, 1033-1, 1033-2, . . . , 1033-N, and the fourth dielectric material 1074-1, 1074-2, . . . , 1074-N, and above the first semiconductor material, 1032-1, 1032-2, . . . , 1032-N, separated by the gate dielectric 1038 and extending into and outward from the plane and orientation of the drawing sheet.

The conductive gate material 1077 may remain in direct electrical contact on a top surface of the first semiconductor material, 1032-1, 1032-2, . . . , 1032-N. In some embodiments, the fourth dielectric material 1074 may be formed below the first dielectric material 1030 while remaining in direct contact with the conductive gate material 1077, the first source/drain region 1075, and the low doped first semiconductor material 1032.

A second semiconductor material 1041, having a second-type dopant (e.g., Phosphorus (P), may be formed within third vertical openings 1072. The second semiconductive material 1041 may be formed as a shared vertical digit line adjacent conductive gate material 1077-1, 1077-2, . . . , 1077-N in third vertical openings 1072, but separated therefrom by fourth dielectric material 1074. The second semiconductive material 1041 may intersect first dielectric material, 1030-1, 1030-2, . . . , 1030-N, the fourth dielectric material 1074-1, 1074-2, . . . , 1074-N, and low doped first semiconductor material 1032-1, 1032-2, . . . , 1032-N. The second semiconductive material 1041 may form shared vertically oriented digit lines adjacent first source/drain regions 1075 on opposing sides.

In some embodiments, the second semiconductive material 1041 may be formed from a silicide. In some embodiments, the second semiconductive material 1041 may comprise a titanium material. In some embodiments, the second semiconductive material 1041 may comprise a titanium nitride (TiN) material. In some embodiments, the second semiconductive material 1041 may comprise a Ruthenium (Ru) material. In some embodiments, the second semiconductive material 1041 may be tungsten (W).

In one embodiment, the first source/drain region 1075 may initially be formed by gas phase doping a high energy gas phase dopant, such as phosphorus (P) atoms, as impurity dopants, at a high plasma energy such as PECVD flowed within the third vertical openings 1072 to form a high concentration, n-type doped (n+) region as the first source/drain regions 1075 in the low doped first semiconductor material 1032, before the second semiconductor material 1041 is deposited within the third vertical openings 1072.

According to various embodiments, the dopant within the second semiconductive material 1041, having the second-type dopant, may be different dopant from the first semiconductor material 1032, having the first-type dopant. For example, the first semiconductor material 1032 may contain a first type dopant of Boron (B) while the second semiconductive material 1041 may contain a second type dopant of Phosphorus (P). A polysilicon material may be deposited into the third vertical openings 1072. For example, a highly phosphorus (P) doped (n+) poly-silicon germanium (SiGe) material may be deposited into third vertical openings 1072 to form the second semiconductive material 1041.

In an alternative embodiment, a highly phosphorus (P) doped (n+) poly-silicon germanium (SiGe) material may first be deposited into third vertical openings 1072 to form the second semiconductive material 1041 and the first source/drain region 1075 may be formed by out-diffusing n-type (n+) dopants into the first semiconductor material, 1032-1, 1032-2, . . . , 1032-N. The highly phosphorus (P) doped (n+) poly-silicon germanium (SiGe) material within the second semiconductive material 1041 may be annealed at a high temperature, e.g., greater than 600 degrees Celsius, to out-diffuse the n-type (n+) dopants (e.g., Phoshorus (P)) into the first semiconductor material, 1032 in order to form the first source/drain regions 1075.

In one embodiment, the plurality of patterned third vertical openings are formed adjacent to where the first source/drain regions 1075 are to be formed, such that when the highly phosphorus doped atoms are out-diffused from the second semiconductor material, the first source/drain regions 1075 will be adjacent the second semiconductive material 1041. The first source/drain regions 1075 may be formed within the low doped first semiconductor material 1032, on both sides of the vertically deposited, second semiconductive material 1041. For example, the first source/drain regions 1075 may be formed by annealing to out-diffuse the n-type (n+) dopant into the low doped first semiconductor material 1032, on both sides of the vertically deposited, second semiconductor material 1041. Fourth dielectric material 1074 may be below the first dielectric material 1030 while remaining in direct contact with the conductive gate material 1077 and the first source/drain region 1075.

FIG. 10D illustrates a cross sectional view, taken along cut-line C-C′ in FIG. 10A, showing another view of the semiconductor structure at this particular point in one example semiconductor fabrication process of an embodiment of the present disclosure. The cross sectional view shown in FIG. 10D is illustrated extending in the second horizontal direction axis (D2) 1005, outside of a region for the horizontally oriented access devices and horizontally oriented storage nodes.

In FIG. 10D, only conductive gate material 1077 may be seen through third dielectric material 1039. Third vertical openings 1072 has been filled by second semiconductive material 1041. The hard mask 1037 may be viewed over third dielectric material 1039.

FIG. 10E illustrates a cross sectional view, taken along cut-line D-D′ in FIG. 10A, showing another view of the semiconductor structure at this particular point in one example semiconductor fabrication process of an embodiment of the present disclosure. The cross sectional view shown in FIG. 10E is illustrated, right to left in the plane of the drawing sheet, extending in the first direction (D1) 1009 along an axis of the repeating iterations of alternating layers of a conductive gate material, 1077-1, 1077-2, . . . , 1077-N, a first dielectric material, 1030-1, 1030-2, . . . , 1030-N, and a first semiconductor material, 1032-1, 1032-2, . . . , 1032-N, intersecting across the plurality of third dielectric fill material 1039.

In FIG. 10E, the conductive gate material, 1077-1, 1077-2, . . . , 1077-N formed on a gate dielectric material 1038, is shown filling in the space in the second vertical opening left by the etched portion of the second dielectric. Third dielectric fill material 1039 is shown spaced along a first direction (D1) 1009 and stacked vertically in arrays extending in the third direction (D3) 1011 in the three dimensional (3D) memory. The conductive gate material, 1077-1, 1077-2, . . . , 1077-N, may fill the openings created by the etched second dielectric material 1033 and the continuous second horizontal openings extending predominantly in the first first horizontal direction axis (D1) 1009 to form horizontal access lines, e.g., 101 in FIG. 1.

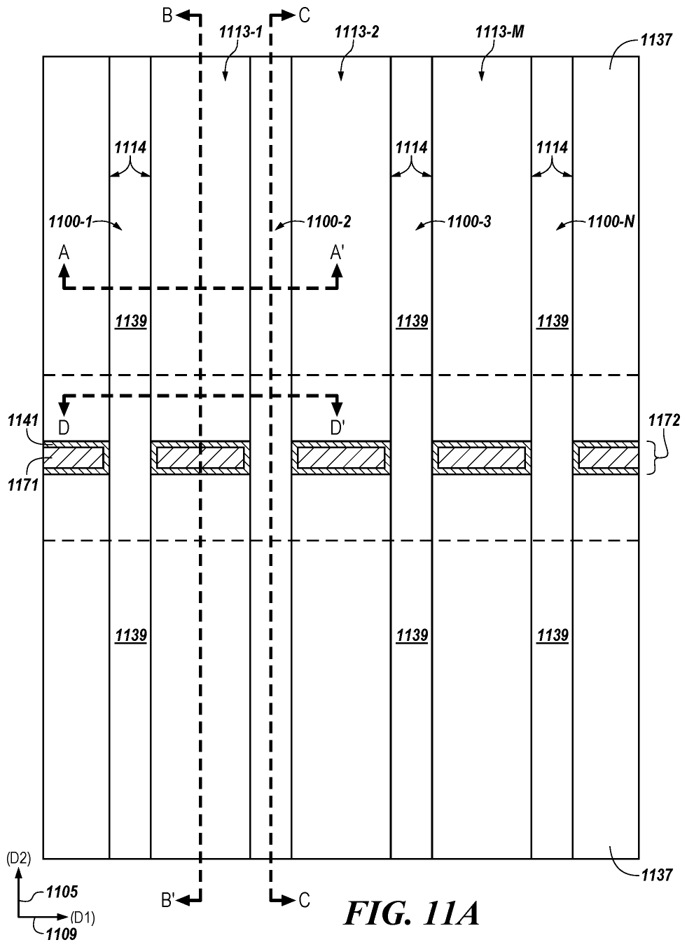

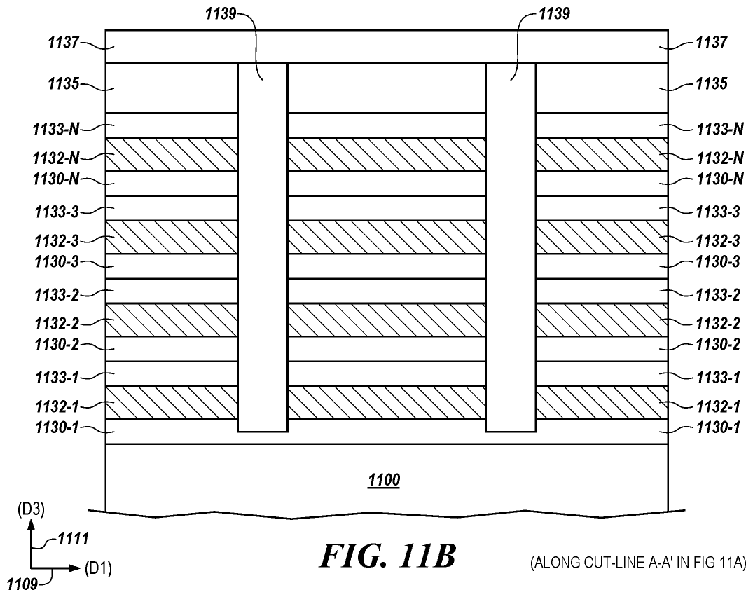

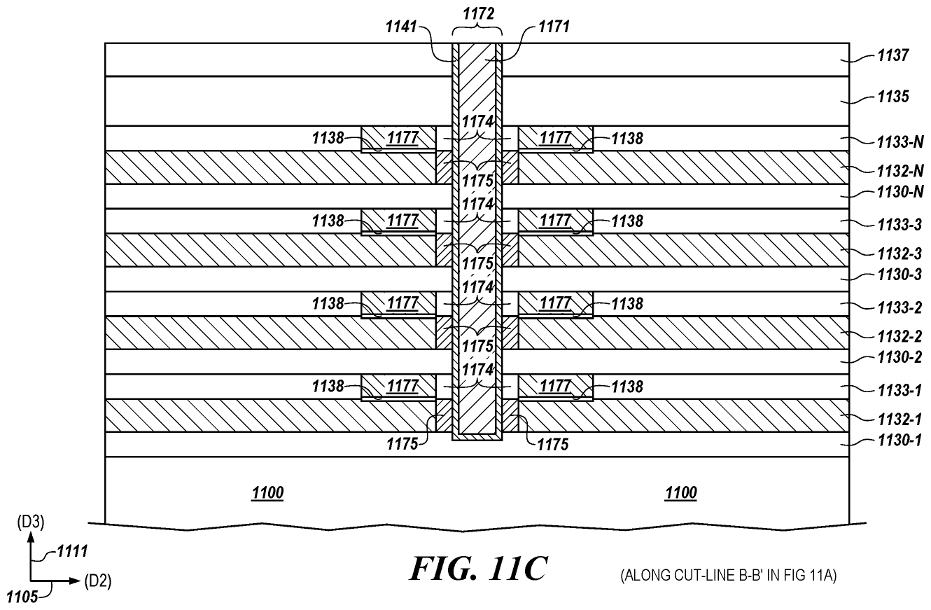

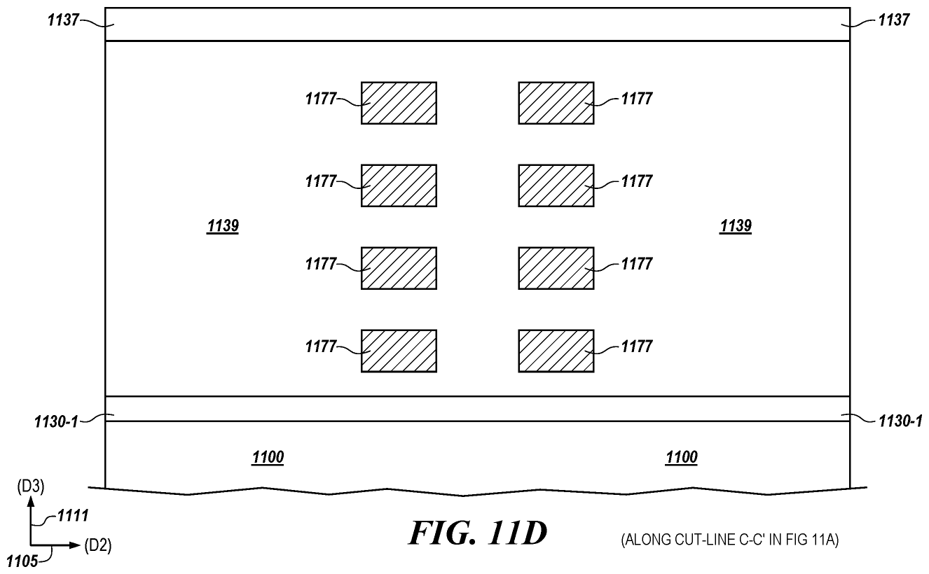

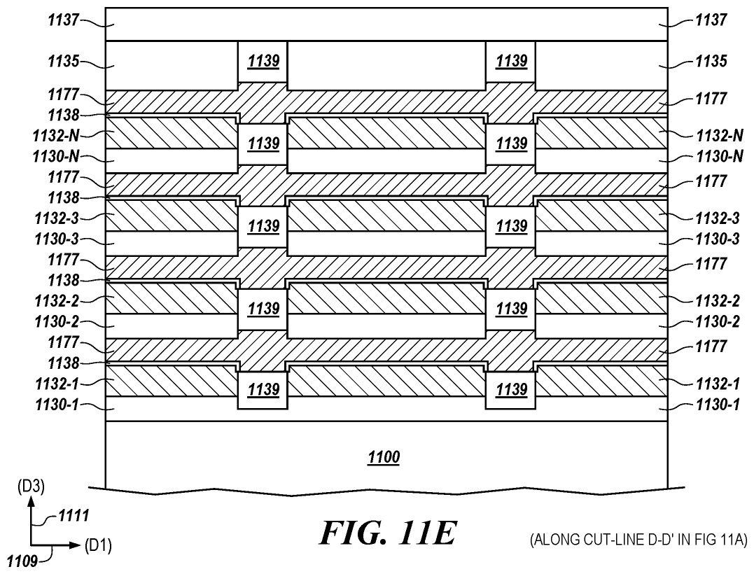

FIG. 11A illustrates an example method, at another stage of a semiconductor fabrication process, for forming arrays of vertically stacked memory cells, having a shared vertical digit line for semiconductor devices and horizontally oriented access lines, such as illustrated in FIGS. 1-3, and in accordance with a number of embodiments of the present disclosure to form a shared vertical digitline, e.g., 103 in FIG. 1. FIG. 11A illustrates a top down view of a semiconductor structure, at a particular point in time, in a semiconductor fabrication process, according to one or more embodiments. In the example embodiment of FIG. 11A, the method comprises forming a metal material 1171 into the second semiconductive material 1141 formed within the plurality of third vertical openings 1172. The metal material 1171 is deposited such that second semiconductive material 1141 surrounds metal material 1171. The third vertical openings 1172, having a first horizontal direction axis (D1) 1109, is not continuous and does not intersect third dielectric material 1139. The second semiconductive material 1141 may be coupled with the metal material 1171 within third vertical openings 1172.

FIG. 11B illustrates a cross sectional view, taken along cut-line A-A′ in FIG. 11A, showing another view of the semiconductor structure at this particular point in one example semiconductor fabrication process of an embodiment of the present disclosure. The cross sectional view shown in FIG. 11B shows repeating iterations of alternating layers of a dielectric material, 1130-1, 1130-2, . . . , 1130-(N+1), a first semiconductor material, 1132-1, 1132-2, . . . , 1132-N, and a second dielectric material, 1133-1, 1133-2, . . . , 1133-N separated by an opening filled with third dielectric material 1139, on a semiconductor substrate 1100 to form the vertical stack. As shown in FIG. 11B, a vertical direction 1111 is illustrated as a third direction (D3), e.g., z-direction in an x-y-z coordinate system, analogous to the third direction (D3) 1111, among first, second, and third directions, shown in FIGS. 1-3. The plane of the drawing sheet, extending right and left, is in a first direction (D1) 1109. In the example embodiment of FIG. 11B, the materials within the vertical stack—a dielectric material, 1130-1, 1130-2, . . . , 1130-(N+1), a first semiconductor material, 1132-1, 1132-2, . . . , 1132-N, and a second dielectric material, 1133-1, 1133-2, . . . , 1133-N are extending into and out of the plane of the drawing sheet in second direction (D2) and along an axis of orientation of the horizontal access devices and horizontal storage nodes of the arrays of vertically stacked memory cells of the three dimensional (3D) memory.

FIG. 11C illustrates a cross sectional view, taken along cut-line B-B′ in FIG. 11A, showing another view of the semiconductor structure at this particular point in one example semiconductor fabrication process of an embodiment of the present disclosure. The cross sectional view shown in FIG. 11C is illustrated extending in the second horizontal direction axis (D2) 1105, left and right along the plane of the drawing sheet, along an axis of the repeating iterations of alternating layers of a first dielectric material, 1130-1, 1130-2, . . . , 1130-N, a first semiconductor material, 1132-1, 1132-2, . . . , 1132-N, and a neighboring, horizontal access line 1177 is illustrated adjacent a second dielectric material, 1133-1, 1133-2, . . . , 1133-N.

In some embodiments, the fourth dielectric material 1174 may be below the first dielectric material 1130 while remaining in direct contact with the conductive gate material 1177. The first source/drain region 1175 may be formed in the low doped first semiconductor material 1132, adjacent vertical second semiconductive material 1141. In one embodiment, the second semiconductive material 1141 may be conformally deposited within the third vertical opening 1172 and the first source/drain region 1175 may be formed by out-diffusing n-type (n+) dopants from the into second semiconductive material 1141 into first semiconductor material 1132. In another embodiment, the first source/drain region 1175 may be formed by gas phase doping a high energy gas phase dopant into the third vertical opening 1172 to form a high concentration, n-type doped (n+) region as the first source/drain regions 1175 in the low doped first semiconductor material 1132, before the second semiconductor material 1141 is deposited within the third vertical openings 1172.

A metal material 1171 may be deposited into the third vertical opening 1172 to fill the third vertical opening 1172. In this embodiment, the second semiconductive material 1141 may be conformally deposited on exposed surfaces of the vertical stack within the third vertical opening 1172 to a particular thickness (tpoly), e.g., using ALD, leaving a vertical opening in a center of the third vertical opening 1172. The metal material 1171 may then be deposited, e.g., using CVD, to fill the center opening within the third vertical opening 1172. For example, the second semiconductive material 1141 may be seen on the outer portions of third vertical opening 1172, in contact with the first source/drain regions 1175, while the metal material 1171 is illustrated on the inner portion of the third vertical opening 1172. In some embodiments, the metal material 1171 may comprise one or more of a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc, and/or some other combination thereof.

The second semiconductive material 1141 may be electrically coupled with the metal material 1171 within third vertical openings 1172. The second semiconductive material 1141 coupled to the metal material 1171 may be formed vertically adjacent fourth dielectric material 1174-1, 1174-2, . . . , 1174-N, the first dielectric material 1130, and the first source/drain regions 1175, filling the third vertical openings 1172 to form the shared vertical digit line on both sides.

FIG. 11D illustrates a cross sectional view, taken along cut-line C-C′ in FIG. 11A, showing another view of the semiconductor structure at this particular point in one example semiconductor fabrication process of an embodiment of the present disclosure. The cross sectional view shown in FIG. 11D is illustrated extending in the second horizontal direction axis (D2) 1105, left and right in the plane of the drawing sheet, outside a region of the horizontally oriented access devices and horizontally oriented storage nodes.

In FIG. 11D, conductive gate material 1177, forming horizontal access lines, may be seen through third dielectric material 1139. Third vertical openings 1172 have been filled by second semiconductive material 1141 and metal material 1171. The hard mask 1137 may be viewed over third dielectric material 1139.

FIG. 11E illustrates a cross sectional view, taken along cut-line D-D′ in FIG. 11A, showing another view of the semiconductor structure at this particular point in one example semiconductor fabrication process of an embodiment of the present disclosure. The cross sectional view shown in FIG. 11E is illustrated, right to left in the plane of the drawing sheet, extending in the first direction (D1) 1109 along an axis of the repeating iterations of alternating layers of a first dielectric material, 1130-1, 1130-2, . . . , 1130-N, a first semiconductor material, 1132-1, 1132-2, . . . , 1132-N, and a second dielectric material, 1133-1, 1133-2, . . . , 1133-N, intersecting across the plurality of separate, horizontal access lines, 1177-1, 1177-2, . . . , 1177-N, and intersecting regions of the first semiconductor material, 1132-1, 1132-2, . . . , 1132-N, separated from the plurality of separate, horizontal access lines, 1177-1, 1177-2, . . . , 1177-N, by the gate dielectric material 1138. In FIG. 11E, the first dielectric fill material 1139 is shown separating the space between neighboring horizontally oriented access devices which may be formed extending into and out from the plane of the drawing sheet as described in connection with FIGS. 4-9, and can be spaced along a first direction (D1) 1109 and stacked vertically in arrays extending in the third direction (D3) 1111 in the three dimensional (3D) memory.

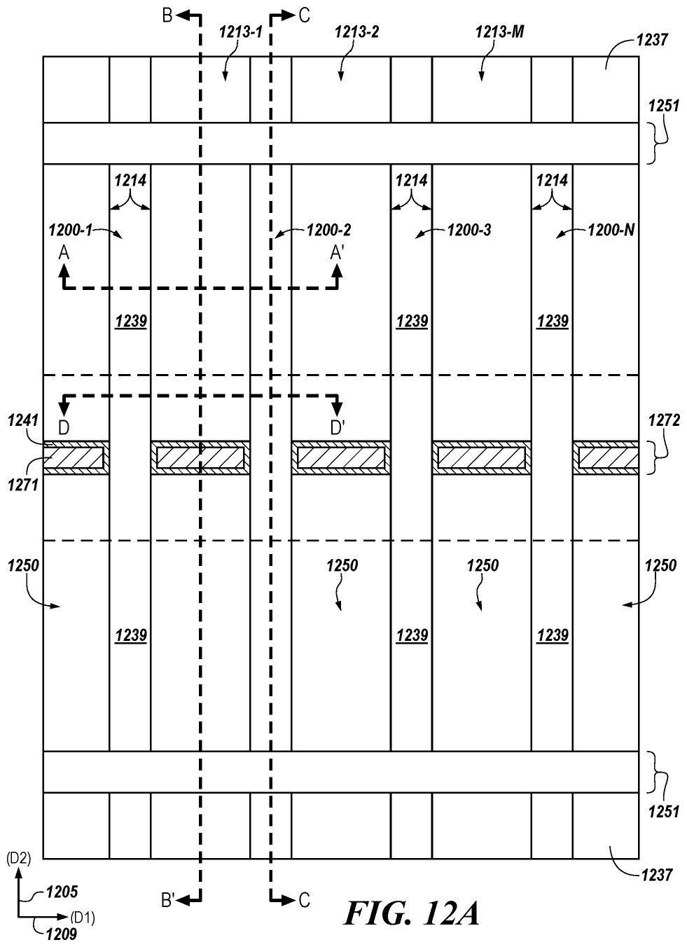

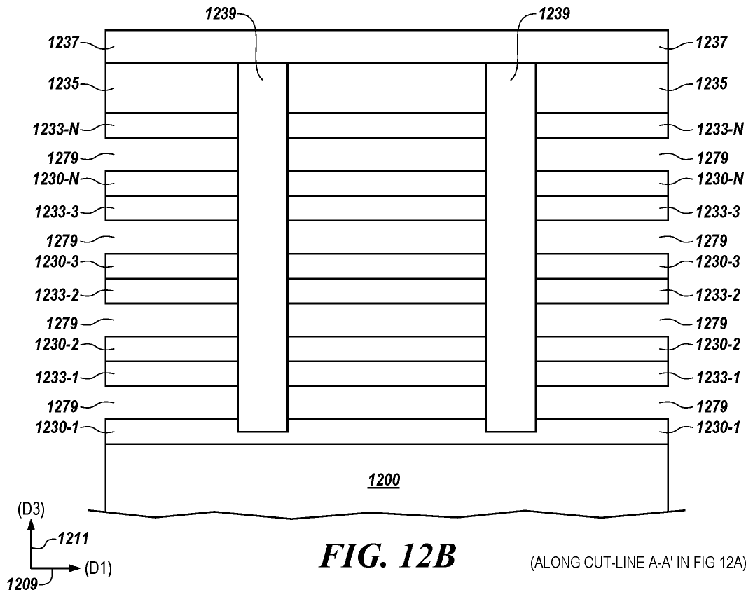

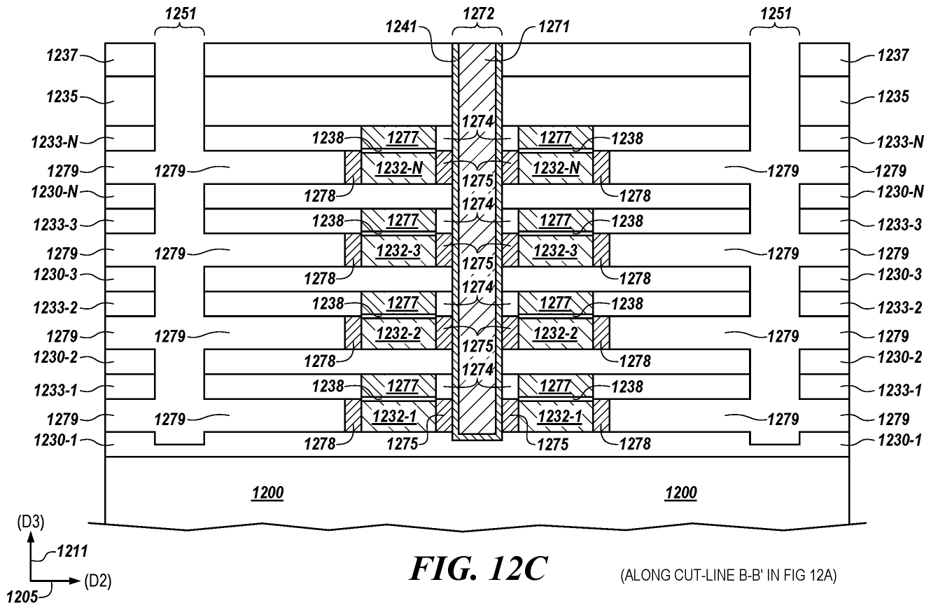

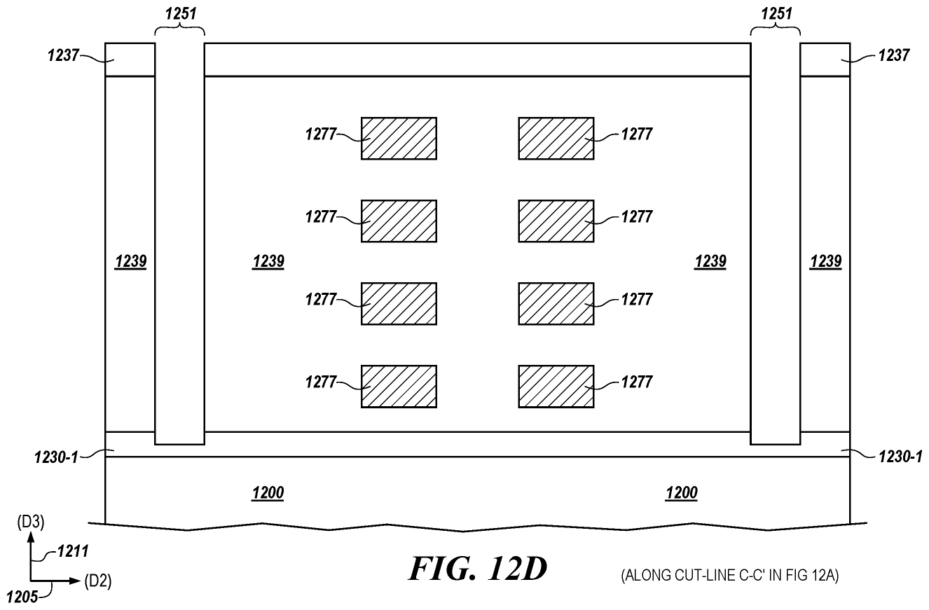

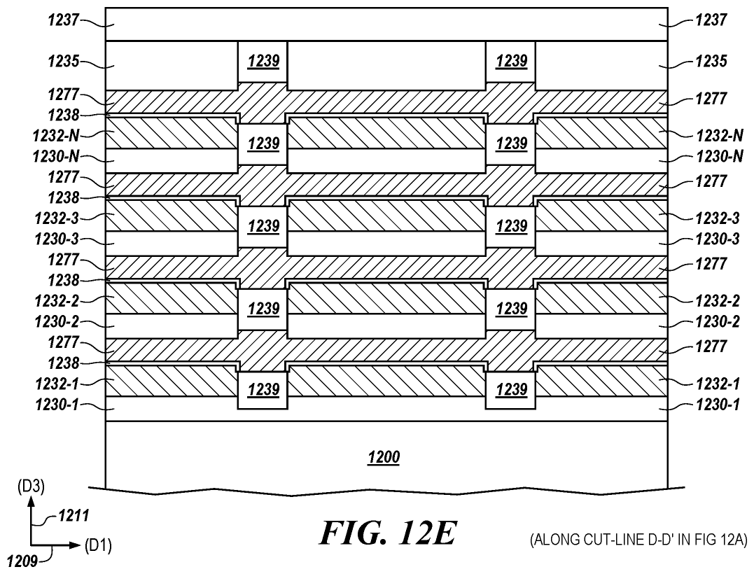

FIG. 12A illustrates an example method, at another stage of a semiconductor fabrication process, for forming arrays of vertically stacked memory cells, having a shared vertical digit line for semiconductor devices and horizontally oriented access lines, such as illustrated in FIGS. 1-3, and in accordance with a number of embodiments of the present disclosure. FIG. 12A illustrates a top down view of a semiconductor structure, at a particular point in time, in a semiconductor fabrication process, according to one or more embodiments for forming storage nodes.

In the example embodiment of FIG. 12A, the method comprises using a photolithographic process to pattern the photolithographic mask 1237. The method in FIG. 12A further illustrates using one or more etchant processes to form a fourth vertical opening 1251 in a storage node region 1250 through the vertical stack and extending predominantly in the first horizontal direction axis (D1) 1209.

The one or more etchant processes forms a fourth vertical opening 1251 to expose third sidewalls in the repeating iterations of alternating layers of a first dielectric material, 1230-1, 1230-2, . . . , 1230-N, a first semiconductor material, 1232-1, 1232-2, . . . , 1232-N, and a second dielectric material, 1233-1, 1233-2, . . . , 1233-N, in the vertical stack, shown in FIGS. 12B-12E, adjacent a second region of the first semiconductor material. A conductive gate material 1277 may be formed above the vertical opening 1251. A metal material 1271 has been formed in second semiconductive material 1241 within the plurality of third vertical openings 1272. The third vertical openings 1272, having a first horizontal direction axis (D1) 1209, is not continuous and does not intersect third dielectric material 1239. The second semiconductive material 1241 may be coupled with the metal material 1271 within third vertical openings 1272.

According to an example embodiment, shown in FIGS. 12B-12E, the method comprises forming a second vertical opening 1251 in the vertical stack (401 in FIG. 4) and selectively etching the second region of the first semiconductor material to form a second horizontal opening a third horizontal distance back from the vertical opening 1251 in the vertical stack (401 in FIG. 4). According to embodiments, selectively etching the second region of the first semiconductor material can comprise using an atomic layer etching (ALE) process. As will be explained more in connection with FIG. 12C, a second source/drain region can be formed in the first semiconductor material at a distal end of the second horizontal openings from the vertical opening.

FIG. 12B illustrates a cross sectional view, taken along cut-line A-A′ in FIG. 12A, showing another view of the semiconductor structure at this particular point in one example semiconductor fabrication process of an embodiment of the present disclosure. The cross sectional view shown in FIG. 12B shows repeating iterations of alternating layers of a dielectric material, 1230-1, 1230-2, . . . , 1230-(N+1), separated by an opening filled with third dielectric material 1239, on a semiconductor substrate 1200 to form the vertical stack. In the example embodiment of FIG. 12B, horizontal opening 1279 is shown with other materials within the vertical stack—a dielectric material, 1230-1, 1230-2, . . . , 1230-(N+1), a and a second dielectric material, 1233-1, 1233-2, . . . , 1233-N extending into and out of the plane of the drawing sheet in second direction (D2) and along an axis of orientation of the horizontal access devices and horizontal storage nodes of the arrays of vertically stacked memory cells of the three dimensional (3D) memory. In one example, an atomic layer etching (ALE) process is used to selectively etch a portion of the first semiconductor material and second horizontal opening 1279 is seen. In the view shown, only second horizontal opening 1279 may be seen, the first semiconductor material is not seen within the vertical stack.

FIG. 12C illustrates a cross sectional view, taken along cut-line B-B′ in FIG. 12A, showing another view of the semiconductor structure at this particular point in one example semiconductor fabrication process of an embodiment of the present disclosure. The cross sectional view shown in FIG. 12C is illustrated extending in the second horizontal direction axis (D2) 1205, left and right along the plane of the drawing sheet, along an axis of the repeating iterations of alternating layers of a first dielectric material, 1230-1, 1230-2, . . . , 1230-N, second horizontal opening 1279, and a second dielectric material, 1233-1, 1233-2, . . . , 1233-N.

In the example embodiment of FIG. 12C, a vertical opening 1251 is shown formed from the mask, patterning and etching process described in connection with FIG. 12A. As shown in FIG. 12C, the first semiconductor material, 1232-1, 1232-2, . . . , 1232-N, in the second region 1244 has been selectively removed to form the second horizontal openings 1279. In one example, an atomic layer etching (ALE) process is used to selectively etch the first semiconductor material, 1232-1, 1232-2, . . . , 1232-N. Horizontally oriented storage nodes, e.g., capacitor cells, may be formed, in the second horizontal openings 1279.

In the middle of the page is shared vertical digit line formed by second semiconductive material 1241 formed around a metal material 1271 within third vertical openings 1272. On either side of the shared vertical digit line is first dielectric material 1230, fourth dielectric material 1274 adjacent conductive gate material 1277 and second dielectric material 1233, and first source/drain region 1275 adjacent low doped first semiconductor material 1232.

In some embodiments, gas phase doping may be used to achieve a highly isotropic e.g., non-directional doping, to form the second source/drain region 1278 to a horizontally oriented access device through fourth vertical openings 1251 and second horizontal openings 1279. In another example, thermal annealing with doping gas, such as phosphorous may be used with a high energy plasma assist to break the bonding. Embodiments, however, are not so limited and other suitable semiconductor fabrication techniques may be utilized.

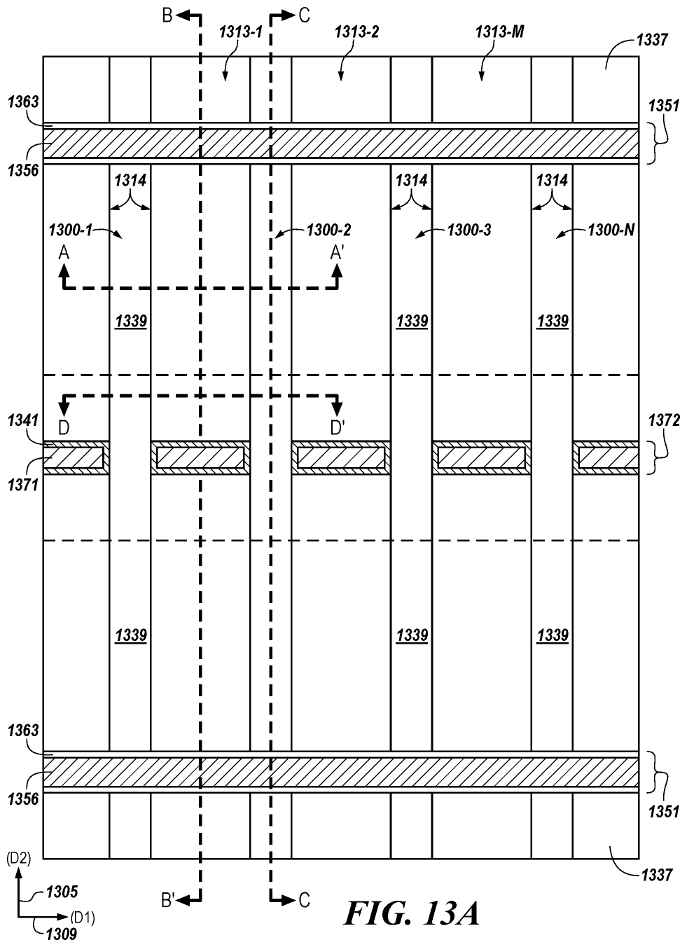

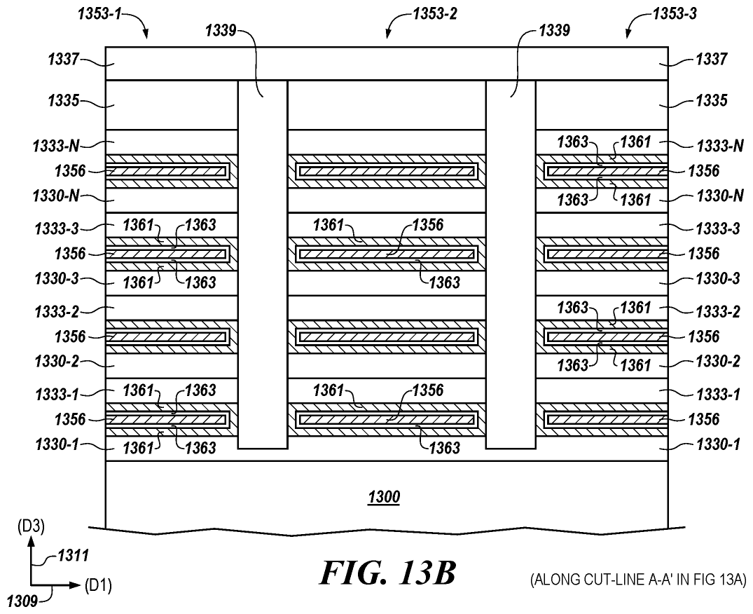

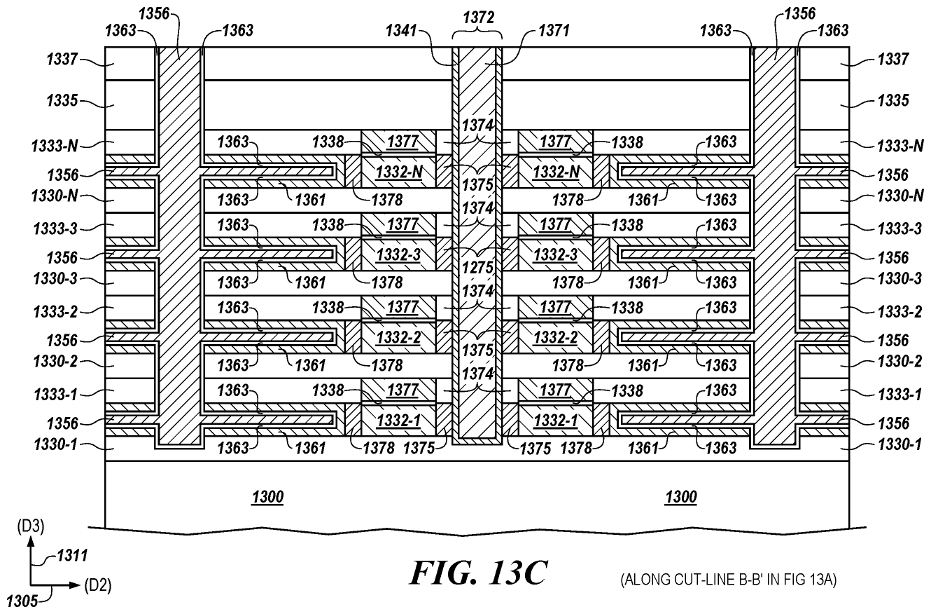

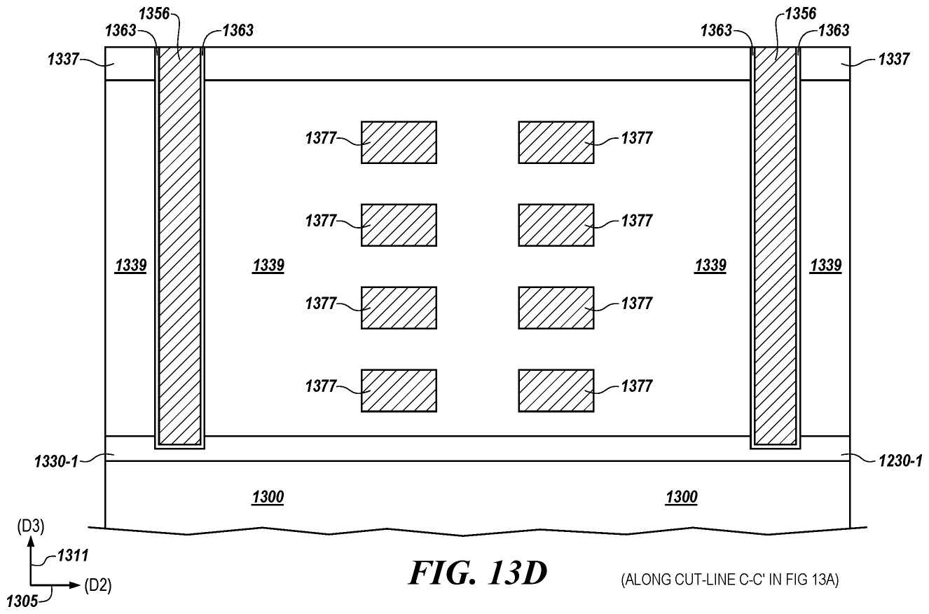

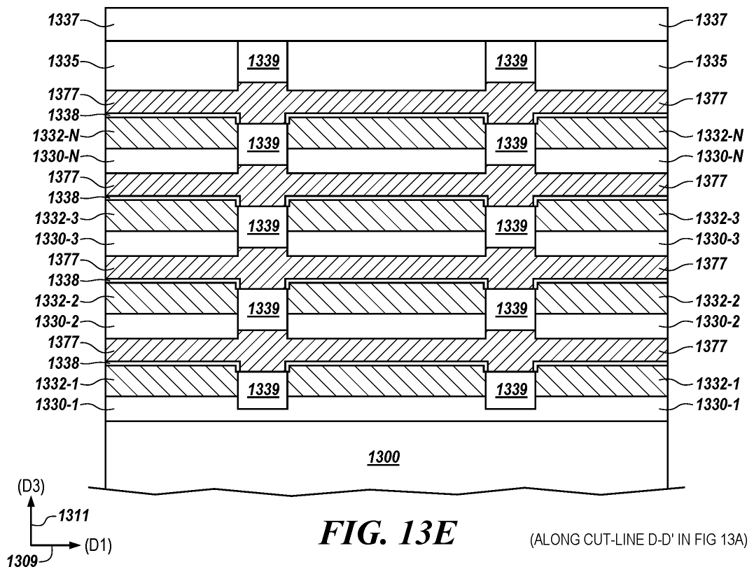

According to one example embodiment, as shown in FIG. 12C a second source/drain region 1278 may be formed by flowing a high energy gas phase dopant, such as Phosphorous (P) for an n-type transistor, into the second horizontal openings 1279 to dope the dopant in the first semiconductor material, 1232-1, 1232-2, . . . , 1232-N, at a distal end of the second horizontal openings 1279 from fourth vertical openings 1251. Fourth vertical openings 1251 may be formed to expose third vertical sidewalls in the vertical stack. The first semiconductor material, 1232-1, 1232-2, . . . , 1232-N, may be selectively etched in the second horizontal direction axis (D2) 1205 to form a plurality of third horizontal openings in the second region. A dopant may be doped in the side surface of the first semiconductor material from second horizontal openings 1279 to form the second source/drain region 1278 horizontally. Horizontally oriented capacitor cells having a bottom electrode (1361 as illustrated in FIG. 13) may be deposited into second horizontal openings 1279 to have electrical contact with the second source/drain region 1278.

FIG. 12D illustrates a cross sectional view, taken along cut-line C-C′ in FIG. 12A, showing another view of the semiconductor structure at this particular point in one example semiconductor fabrication process of an embodiment of the present disclosure. The cross sectional view shown in FIG. 12D is illustrated extending in the second horizontal direction axis (D2) 1205, left and right in the plane of the drawing sheet, outside of a region in which the horizontally oriented access devices and horizontally oriented storage nodes, e.g., capacitor cells, will be formed In FIG. 12D, conductive gate material 1277 may be seen through third dielectric material 1239. At both ends of the drawing sheet fourth vertical openings 1251 are shown. The hard mask 1237 may be viewed over third dielectric material 1239.

FIG. 12E illustrates a cross sectional view, taken along cut-line D-D′ in FIG. 12A, showing another view of the semiconductor structure at this particular point in one example semiconductor fabrication process of an embodiment of the present disclosure. The cross sectional view shown in FIG. 12E is illustrated, right to left in the plane of the drawing sheet, extending in the first direction (D1) 1209 along an axis of the repeating iterations of alternating layers of a first dielectric material, 1230-1, 1230-2, . . . , 1230-N, a first semiconductor material, 1232-1, 1232-2, . . . , 1232-N, and a second dielectric material, 1233-1, 1233-2, . . . , 1233-N, intersecting across the plurality of separate, horizontal access lines, 1277-1, 1277-2, . . . , 1277-N, and intersecting regions of the first semiconductor material, 1 232-1, 1232-2, . . . , 1232-N, separated from the plurality of separate, horizontal access lines, 1277-1, 1277-2, . . . , 1277-N, by the gate dielectric material 1238. In FIG. 12E, the first dielectric fill material 1239 is shown separating the space between neighboring horizontally oriented access devices and horizontally oriented storage nodes, which may be formed extending into and out from the plane of the drawing sheet as described in more detail below, and can be spaced along a first direction (D1) 1209 and stacked vertically in arrays extending in the third direction (D3) 1211 in the three dimensional (3D) memory.

FIG. 13A illustrates an example method, at another stage of a semiconductor fabrication process, for forming arrays of vertically stacked memory cells, having a shared vertical digit line for semiconductor devices and horizontally oriented access lines, in accordance with a number of embodiments of the present disclosure. FIG. 13A illustrates a top down view of a semiconductor structure, at a particular point in time, in a semiconductor fabrication process, according to one or more embodiments.

In the example embodiment of FIG. 13A, the method comprises using a photolithographic process to pattern the photolithographic mask 1337. The method in FIG. 13A further illustrates using one or more etchant processes to form fourth vertical openings 1351 through the vertical stack and extending predominantly in the first horizontal direction axis (D1) 1309. The one or more etchant processes forms a vertical opening 1351 to expose third sidewalls in the repeating iterations of alternating layers of a first dielectric material, 1330-1, 1330-2, . . . , 1330-N, a first semiconductor material, 1332-1, 1332-2, . . . , 1332-N, and a second dielectric material, 1333-1, 1333-2, . . . , 1333-N, in the vertical stack, shown in FIGS. 13B-13E, adjacent a second region of the first semiconductor material. A metal material 1371 has been formed into the second semiconductive material 1341 within the plurality of third vertical openings 1372. The metal material 1371 is deposited such that second semiconductive material 1341 surrounds metal material 1371.

In some embodiments, as shown in FIGS. 13B-13E, the method comprises forming capacitor cell as the storage node in the second horizontal opening. By way of example, and not by way of limitation, forming the capacitor comprises using an atomic layer deposition (ALD) process to sequentially deposit, in the second horizontal opening, a first electrode 1361 and a second electrode 1356 separated by a cell dielectric 1363 within fourth vertical openings 1351. Other suitable semiconductor fabrication techniques and/or storage nodes structures may be used.

FIG. 13B illustrates a cross sectional view, taken along cut-line A-A′ in FIG. 13A, showing another view of the semiconductor structure at this particular point in one example semiconductor fabrication process of an embodiment of the present disclosure. The cross sectional view shown in FIG. 13B is away from the plurality of separate, horizontal access lines, 1377-1, 1377-2, . . . , 1377-N, 1377-(N+1), . . . , 1377-(Z-1), and shows repeating iterations of alternating layers of a dielectric material, 1330-1, 1330-2, . . . , 1330-(N+1), separated by horizontally oriented capacitor cells having first electrodes 1361, e.g., bottom cell contact electrodes, cell dielectrics 1363, and second electrodes 1356, e.g., top, common node electrodes, on a semiconductor substrate 1300 to form the vertical stack. As shown in FIG. 8B, a vertical direction 1311 is illustrated as a third direction (D3), e.g., z-direction in an x-y-z coordinate system, analogous to the third direction (D3) 1311, among first, second, and third directions, shown in FIGS. 1-3. The plane of the drawing sheet, extending right and left, is in a first direction (D1) 1309. In the example embodiment of FIG. 13B, the first electrodes 1361, e.g., bottom electrodes to be coupled to source/drain regions of horizontal access devices, and second electrodes 1356 are illustrated separated by a cell dielectric material 1363 extending into and out of the plane of the drawing sheet in second direction (D2) and along an axis of orientation of the horizontal access devices and horizontal storage nodes of the arrays of vertically stacked memory cells of the three dimensional (3D) memory.

FIG. 13C illustrates a cross sectional view, taken along cut-line B-B′ in FIG. 13A, showing another view of the semiconductor structure at this particular point in one example semiconductor fabrication process of an embodiment of the present disclosure. The cross sectional view shown in FIG. 13C is illustrated extending in the second horizontal direction axis (D2) 1305, left and right along the plane of the drawing sheet, along an axis of the repeating iterations of alternating layers of a first dielectric material, 1330-1, 1330-2, . . . , 1330-N, a first semiconductor material, 1332-1, 1332-2, . . . , 1332-N, and a second dielectric material, 1333-1, 1333-2, . . . , 1333-N, along and in which the horizontally oriented access devices and horizontally oriented storage nodes, e.g., capacitor cells, can be formed within the layers of second horizontal opening. In the example embodiment of FIG. 13C, first electrodes 1361, e.g., bottom electrodes to be coupled to source/drain regions of horizontal access devices, and second electrodes 1356, e.g., top electrodes to be coupled to a common electrode plane such as a ground plane, separated by cell dielectrics 1363, are shown. However, embodiments are not limited to this example.

In the example embodiment of FIG. 13C, the horizontally oriented storage nodes having the first electrodes 1361, e.g., bottom electrodes to be coupled to source/drain regions of horizontal access devices, and second electrodes 1356, e.g., top electrodes to be coupled to a common electrode plane such as a ground plane, are shown formed in a second horizontal opening, extending in second direction (D2), left and right in the plane of the drawing sheet. The second electrodes 1356 separated by cell dielectrics 1363 are also shown to fill fourth vertical openings (1251 as shown in FIG. 12) , and along an axis of orientation of the horizontal access devices and horizontal storage nodes of the arrays of vertically stacked memory cells of the three dimensional (3D) memory.

FIG. 13D illustrates a cross sectional view, taken along cut-line C-C′ in FIG. 13A, showing another view of the semiconductor structure at this particular point in one example semiconductor fabrication process of an embodiment of the present disclosure. The cross sectional view shown in FIG. 13D is illustrated extending in the second horizontal direction axis (D2) 1305, left and right in the plane of the drawing sheet, outside of a region in which the horizontally oriented access devices and horizontally oriented storage nodes, e.g., capacitor cells. In FIG. 13C, the third dielectric material 1339 is shown filling the space between the horizontally oriented access devices, which can be spaced along a first direction (D1), extending into and out from the plane of the drawings sheet, for a three dimensional array of vertically oriented memory cells. Conductive gate material 1377 may be seen through third dielectric material 1239. At both ends of the drawing sheet the second electrode 1356, e.g., top, common electrode to a capacitor cell structure, separated by cell dielectrics 1362 may be seen. The hard mask 1237 may be viewed over third dielectric material 1139.

FIG. 13E illustrates a cross sectional view, taken along cut-line D-D′ in FIG. 13A, showing another view of the semiconductor structure at this particular point in one example semiconductor fabrication process of an embodiment of the present disclosure. The cross sectional view shown in FIG. 13E is illustrated, right to left in the plane of the drawing sheet, extending in the first direction (D1) 1309 along an axis of the repeating iterations of alternating layers of a first dielectric material, 1330-1, 1330-2, . . . , 1330-N, a first semiconductor material, 1332-1, 1332-2, . . . , 1332-N, and a second dielectric material, 1333-1, 1333-2, . . . , 1333-N, intersecting across the plurality of separate, horizontal access lines, 1377-1, 1377-2, . . . , 1377-N, and intersecting regions of the first semiconductor material, 1332-1, 1332-2, . . . , 1332-N, in which a channel region may be formed, separated from the plurality of separate, horizontal access lines, 1377-1, 1377-2, . . . , 1377-N, by the gate dielectric material 1338. In FIG. 13E, the first dielectric fill material 1339 is shown separating the space between neighboring horizontally oriented access devices and horizontally oriented storage nodes, which may be formed extending into and out from the plane of the drawing sheet as described in more detail below, and can be spaced along a first direction (D1) 1309 and stacked vertically in arrays extending in the third direction (D3) 1311 in the three dimensional (3D) memory.

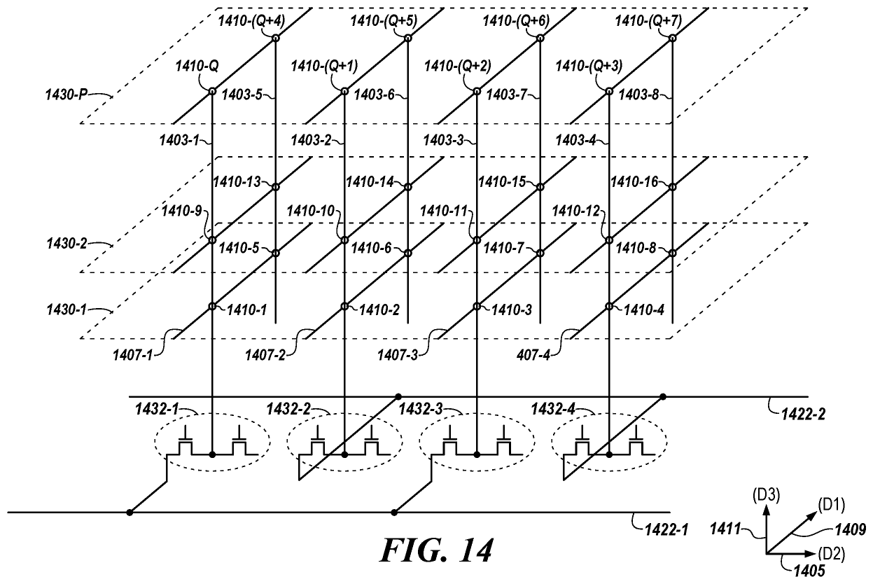

FIG. 14 is an example of a multiplexor for a semiconductor device, in accordance a number of embodiments of the present disclosure. The vertical 3D memory illustrated in FIG. 14 is analogous to that illustrated in FIGS. 1-3, but shown from a different perspective and with a different level of detail. A portion of a plurality of vertically stacked tiers 1430-1, 1430-2, . . . , 1430-P of memory cells in an array are illustrated. The tiers 1430 are stacked vertically in the third direction 1411 (D3). Also running through the tiers 1430 in the third direction 1411 (D3) are a plurality of vertical sense lines, such as vertical sense lines 1403-1 to 1403-8. Each vertical sense line 1403 is coupled to one memory cell 1410 in each tier 1430.

Each tier 1430-1, 1430-2, . . . , 1430-P can include memory cells coupled to respective horizontal access lines that that each run along the first direction 1409 (D1) in parallel to each other. As an example, as illustrated in FIG. 14, a tier 1430-1 includes memory cells 1410-1 and 1410-5 (coupled to a horizontal access line 1407-1 and vertical sense lines 1403-1 and 1403-5, respectively), and memory cells 1410-2 and 1410-6 (coupled to a horizontal access line 1407-2 and vertical sense lines 1403-2 and 1403-6, respectively), memory cells 1410-3 and 1410-7 (coupled to a horizontal access line 1407-3 and vertical sense lines 1403-3 and 1403-7, respectively), and memory cells 1410-4 and 1410-8 (coupled to a horizontal access line 1407-4 and vertical sense lines 1403-4 and 1403-8, respectively). Similarly, a tier 1430-2 can include memory cells 1410-9 and 1410-13 (coupled to a same horizontal access line and vertical sense lines 1403-1 and 1403-5, respectively), 1410-10 and 1410-14 (coupled to a same horizontal access line and vertical sense lines 1403-2 and 1403-6, respectively), 1410-11 and 1410-15 (coupled to a same horizontal access line and vertical sense lines 1403-3 and 1403-7, respectively), and 1410-12 and 1410-16 (coupled to a same horizontal access line and vertical sense lines 1403-4 and 1403-8, respectively). Similarly, a tier 1430-P can include 1410-Q and 1410-(Q+4) (coupled to a same horizontal access line and vertical sense lines 1403-1 and 1403-5, respectively), 1410-(Q+1) and 1410-(Q+5) (coupled to a same horizontal access line and vertical sense lines 1403-2 and 1403-6, respectively), 1410-(Q+2) and 1410-(Q+6) (coupled to a same horizontal access line and vertical sense lines 1403-3 and 1403-7, respectively), and 1410-(Q+3) and 1410-(Q+7) (coupled to a same horizontal access line and vertical sense lines 1403-4 and 1403-8, respectively), as illustrated in FIG. 14. Further, each tier 1430 intersects a plurality of vertical sense lines 1403, which run in the third direction 1411 (D3).

As further illustrated in FIG. 14, the vertical sense lines 1403-1 to 1403-4 are coupled to a respective one of a pair of horizontal sense lines 1422-1 and 1422-2 via a respective multiplexor 1432-1 to 1432-4 that are formed under the array of vertically stacked memory cells. For example, as illustrated in FIG. 14, the vertical sense lines 1403-1 and 1403-3 are coupled to the horizontal sense line 1422-1 via multiplexors 1432-1 and 1432-3, respectively, and the vertical sense lines 1403-2 and 1403-4 are coupled to the horizontal sense line 1422-2 via multiplexors 1432-2 and 1432-4, respectively. As illustrated in connection with FIG. 14, vertical sense lines 1403 include alternating vertical sense lines along the pair of horizontal sense lines 1422.

The multiplexor 1432-1 can operate to electrically couple/decouple the vertical sense line 1403-1 to/from the horizontal sense line 1422-1 (such that one of the memory cells 1410-1, 1410-9, and 1410-Q can be accessed); the multiplexor 1432-2 can operate to electrically couple/decouple the vertical sense line 1403-2 to/from the horizontal sense line 1422-2 (such that one of the memory cells 1410-2, 1410-10, and 1410-(Q+1) can be accessed); the multiplexor 1432-3 can operate to electrically couple/decouple the vertical sense line 1403-3 to/from the horizontal sense line 1422-1 (such that one of the memory cells 1410-3, 1410-11, and 1410-(Q+2) can be accessed); and the multiplexor 1432-4 can operate to electrically couple/decouple the vertical sense line 1403-4 to/from the horizontal sense line 1422-2 (such that one of the memory cells 1410-4, 1410-12, and 1410-(Q+3) can be accessed).

As described herein, each multiplexor can operate to electrically couple/decouple a vertical sense line to/from a respective horizontal sense line. Although not shown in FIG. 14, a pair of horizontal sense lines 1422-1 and 1422-2 can be coupled to a sense amplifier. To sense a memory cell, the control circuitry can cause two multiplexers that are adjacent to each other and coupled to a pair of horizontal sense lines 1422 to electrically couple one vertical sense line (to which the memory cell to be sensed is coupled) to one of the pair of horizontal sense lines and another vertical sense line to a different one of the pair of horizontal sense lines. For example, to sense the memory cell 1410-1, the control circuitry can cause the multiplexor 1432-1 to electrically couple the vertical sense line 1403-1 to the horizontal sense line 1422-1 and cause the multiplexor 1432-2 to electrically couple the vertical sense line 1403-2 to the horizontal sense line 1422-1, while causing remaining multiplexors 1432-3 and 1432-4 to decouple remaining vertical sense lines (e.g., vertical sense lines 1403-3 and 1403-4) from respective horizontal sense lines 1422-1 and 1422-2. The control circuitry can further activate an access line driver to provide a positive power supply to the horizontal access line 1407-1, which will further provide a differential voltage (e.g., a voltage difference between the vertical sense lines 1403-1 and 1403-2) to the sense amplifier via horizontal sense lines 1422-1 and 1422-2.

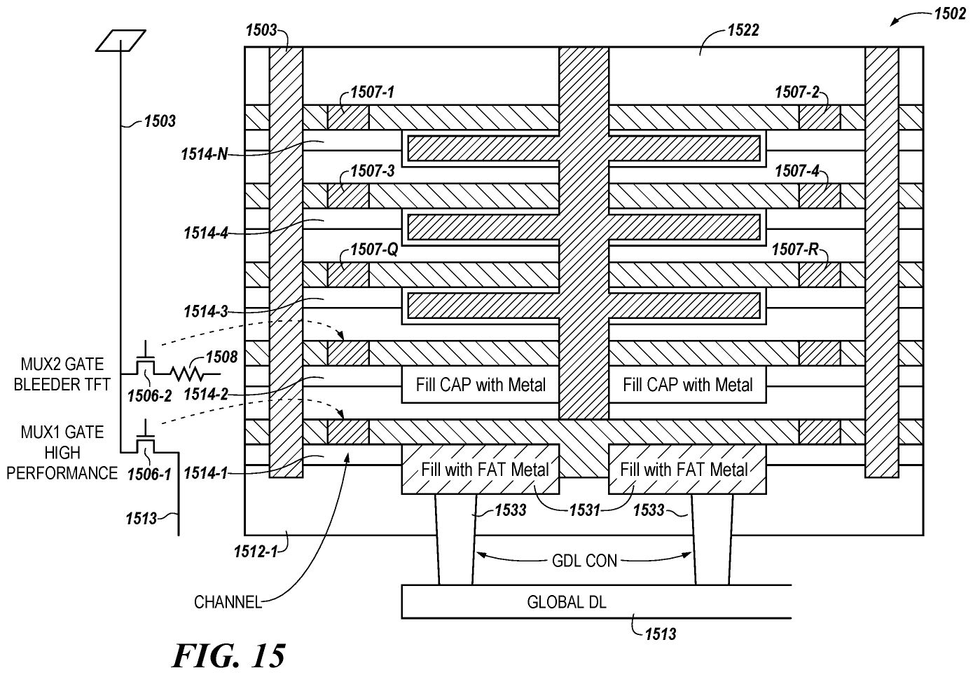

FIG. 15 is an example of a multiplexor coupled to an example horizontally oriented access device and access lines and shared vertically oriented digit lines for semiconductor devices, in accordance with a number of embodiments of the present disclosure. As shown in FIG. 15, the vertical stack 1502 can include repeating, alternating layers of a first dielectric material 1512-1, 1512-2, 1512-3, 1512-4, . . . , 1512-N, a semiconductor material 1514-1, 1514-2, 1514-3, 1514-4, . . . , 1514-N, and a second dielectric material 1516-1, 1516-2, 1516-3, 1516-4, . . . , 1516-N. In some embodiments, at least two (2) repeating iterations of the alternating layers may be formed to form the vertical stack 1502 to a height in a range of twenty (20) nanometers (nm) to three hundred (300) nm. The layers of semiconductor material 1514 can also be referred to as channels 1514. In some embodiments, the first dielectric material 1512, the semiconductor material 1514, and the second dielectric material 1516 may be formed using a chemical vapor deposition (CVD) process. In one embodiment, the first dielectric material 1512 can be deposited to have a thickness (e.g., vertical height) in the third direction (D3), in a range of 20 nm to sixty (60) nm. In one embodiment, the semiconductor material 1514 can be deposited to have a thickness (e.g., vertical height) in a range of ten (10) nm to thirty (30) nm. In one embodiment, the second dielectric material 416 can be deposited to have a thickness (e.g., vertical height), in a range of 20 nm to one hundred and fifty (150) nm. Embodiments, however, are not limited to these examples. As shown in FIG. 15, a vertical direction 1511 is illustrated as a third direction (D3) (e.g., z-direction in an x-y-z coordinate system) analogous to the third direction (D3) among first, second, and third directions, shown in FIGS. 1-3. The vertical stack 1502 can also include a dielectric cap 1522.

In some embodiments, the first dielectric material 1512 may be an interlayer dielectric (ILD). By way of example, and not by way of limitation, the first dielectric material 1512 may comprise an oxide material, e.g., SiO2. In another example the first dielectric material 1512 may comprise a silicon nitride (Si3N₄) material (also referred to herein as “SiN”). In another example the first dielectric material 1512 may comprise a silicon oxy-carbide (SiOxCy) material. In another example the first dielectric material 1512 may include silicon oxy-nitride (SiOxNy) material (also referred to herein as “SiON”), and/or combinations thereof. Embodiments are not limited to these examples.

In some embodiments, the second dielectric material 1516 may be an interlayer dielectric (ILD). By way of example, and not by way of limitation, the second dielectric material 1516 may comprise a nitride material. The nitride material may be a silicon nitride (Si3N₄) material. In another example the second dielectric material 1516 may comprise a silicon oxy-carbide (SiOC) material. In another example the second dielectric material 1516 may include silicon oxy-nitride (SiON), and/or combinations thereof. Embodiments are not limited to these examples. However, according to embodiments, the second dielectric material 1516 is purposefully chosen to be different in material or composition than the first dielectric material 1512 such that a selective etch process may be performed on one of the first and second dielectric layers, selective to the other one of the first and the second dielectric layers (e.g., the second SiN dielectric material 1516 may be selectively etched relative to the semiconductor material 1514 and a first oxide dielectric material 1512).

In some embodiments the semiconductor material 1514 may comprise a silicon (Si) material in a polycrystalline and/or amorphous state. The semiconductor material 1514 may be a low doped, p-type (p−) silicon material. The semiconductor material 1514 may be formed by gas phase doping boron atoms (B), as an impurity dopant, at a low concentration to form the low doped, p-type (p−) silicon material. In some embodiments, the semiconductor material 1516 may be formed by gas phase doping boron atoms (B) in-situ. The low doped, p-type (p−) silicon material may be an amorphous silicon material. Embodiments, however, are not limited to these examples.

The vertical stack 1502 can also include a sense line 1503 and a plurality of access lines 1507-1, 1507-2, . . . , 1507-Q. In some embodiments, the sense line 1503 can be a vertical sense line that intersects and makes contact with each of the layers of the vertical stack 1502. In some embodiments, the access lines 1507 may be horizontal access lines 1507 and may be formed in the semiconductor material 1516 layers of the vertical stack 1502. The vertical stack 1502 may also include a dielectric material 1524 to isolate multiple vertical stacks 1502, horizontally oriented storage nodes 1537 (e.g., capacitor cells), and vertical portions of the storage nodes 1518-1.

The vertical stack 1502 may also include a multiplexor 1520. As used herein, the term “multiplexor” refers to circuitry to select one of multiple vertical and/or horizontal sense lines. As shown in FIG. 15, in some embodiments, the multiplexor 1520 can be the bottom portion of the vertical stack 1502. In some embodiments, the multiplexor 1520 can be coupled to digit lines (such as shared vertically oriented digit lines, described herein) to select between two adjacent horizontal access devices. In some embodiments, the multiplexor 1520 can include the first dielectric material 1512, the semiconductor material 1514, the second dielectric material 1516, and the sense line 1503 (e.g., local sense line) of the vertical stack 1502. However, instead of access lines (e.g., access lines 1507), a first multiplexor switch 1506-1 and a second multiplexor switch 1506-2 are formed in the semiconductor material 1516. In some embodiments, the multiplexor switches 1506 may be formed in an area of the semiconductor material 1516 corresponding to an area of the semiconductor material 1516 in which the access lines 1507 are formed, such that the multiplexor switches 1506 are in a vertical alignment with the access lines 1507. The first multiplexor switch 1506-1 comprises a first gate and the second multiplexor switch 1506-2 comprises a second gate. In some embodiments, the first gate and the second gate run parallel to and vertically in line with a respective horizontal access line 1507 in each of the plurality of tiers. As shown in FIG. 15, the multiplexor switches 1506 can be below the access lines 1507. The first layer of semiconductor material 1514-1 can function as a channel for the first multiplexor switch 1506-1 and the second layer of the semiconductor material 1514-2 can function as a channel for the second multiplexor switch 1506-2. Subsequent layers of the semiconductor material (e.g., semiconductor material 1514-3, 1514-4, . . . , 1514-N) can function as channels for memory cells (e.g., memory cell 110 in FIG. 1).

The first multiplexor switch 1506-1 and the second multiplexor switch 1506-2 can be selectively coupled to the same respective vertical sense line (e.g., sense line 1503) as the access lines 1507 in the vertical stack 1502. A first terminal (e.g., source/drain region) of the first multiplexor switch 1506-1 can be coupled to the sense line 1503 and a second terminal of the first multiplexor switch 1506-1 can be coupled to a horizontal (e.g., global) sense line 1513. The first multiplexor switch 1506-1 can couple to the horizontal sense line 1513 through the first metal fill 1531 coupled to the second terminal of the first multiplexor switch 1506-1 and a metal line (e.g., horizontal sense line contact) 1533 that is coupled to the horizontal sense line 1513. The area in which the first metal fill 1531 is deposited can be filled with “fat” metal (e.g., filled with metal to a thickness greater than that of the second metal fill 1508 discussed below). Applying a voltage to the gate of the first multiplexor switch 1506-1 may electronically couple the local sense line 1503 to the horizontal sense line 1513. The first multiplexor gate (mux1 gate) can be configured for high performance.

A first terminal of the second multiplexor switch 1506-2 may be coupled to the sense line 1503 and a second terminal of the second multiplexor switch can include a second metal fill 1508. In some embodiments, the second metal fill 1508 may be deposited in a horizontal opening parallel to and substantially similar to the horizontal openings in which the capacitor material is deposited. Due to the thickness at which the second metal fill 1508 may be deposited, the second metal fill 1508 may function as a resistor and restrict the flow of current through the second terminal of the second multiplexor switch 1506-2. The second metal fill 1508 can be used to discharge the voltage stored in a capacitor when voltage is no longer being applied to the capacitor. In some embodiments, the second metal fill 1508 may be coupled to the capacitor 1537. Applying a voltage to a gate of the second multiplexor switch 1506-2 may couple the second metal fill 1508 to the capacitor 1537 to discharge any charge stored in the capacitor 1537. Applying a voltage to the gate of the second multiplexor switch 1506-2 can also precharge the vertical sense line 1503.

In some embodiments, a second terminal of the first multiplexor switch 1506-1 can have a first vertical thickness and be coupled to a respective horizontal sense line 1513. Further, a second terminal of the second multiplexor switch 1506-2 can have a second vertical thickness that is less than the first vertical thickness. The difference in vertical thickness can cause the second terminal of the first multiplexor switch 1506-1 to have a higher resistance than the second terminal of the second multiplexor switch 1506-2. In some embodiments, the second terminal of the first multiplexor switch 1506-1 and the second terminal of the second multiplexor switch 1506-2 run parallel to and vertically in line with a plurality of storage nodes in a particular vertical stack of memory cells.

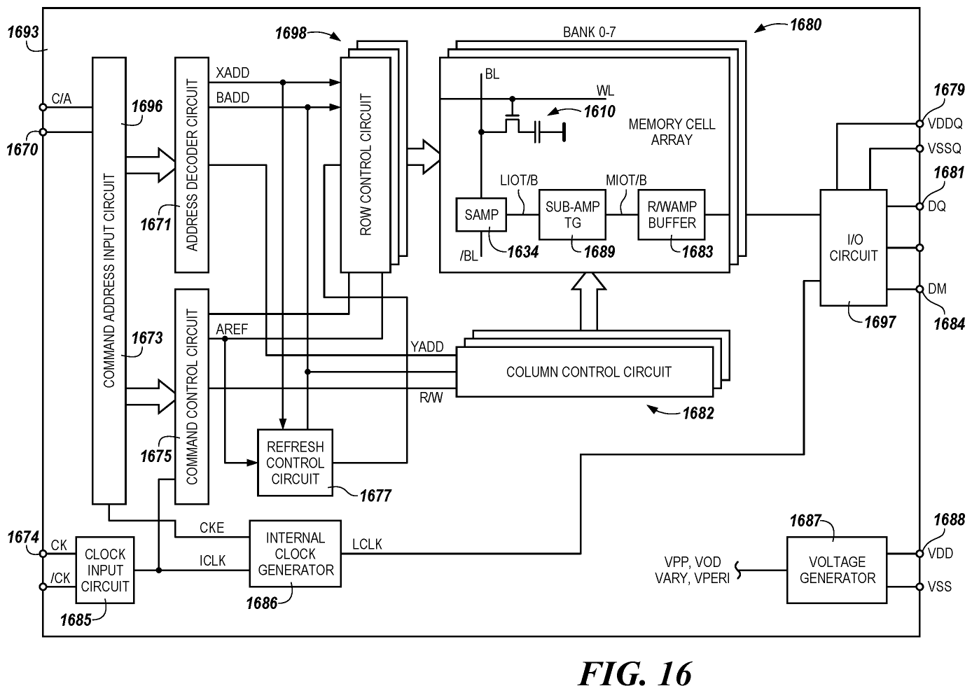

FIG. 16 is a block diagram of an apparatus in the form of a computing system including a memory device 1693 in accordance with a number of embodiments of the present disclosure. As used herein, a memory device 1693, a memory array 1680, and/or a host (not pictured), for example, might also be separately considered an “apparatus.”

In this example, system 1690 includes a host (not pictured) coupled to memory device 1693 via an interface. The computing system can be a personal laptop computer, a desktop computer, a digital camera, a mobile telephone, a memory card reader, or an Internet-of-Things (IoT) enabled device, among various other types of systems. The host can include a number of processing resources (e.g., one or more processors, microprocessors, or some other type of controlling circuitry) capable of accessing the memory device 1693. The system can include separate integrated circuits, or both the host and the memory device 1693 can be on the same integrated circuit. For example, the host may be a system controller of a memory system comprising multiple memory devices 1693, with the system controller (not pictured) providing access to the respective memory devices 1693 by another processing resource such as a central processing unit (CPU).

In the example shown in FIG. 16, the host is responsible for executing an operating system (OS) and/or various applications (e.g., processes) that can be loaded thereto (e.g., from memory device 1693 via a controller). The OS and/or various applications can be loaded from the memory device 1693 by providing access commands from the host to the memory device 1693 to access the data comprising the OS and/or the various applications. The host can also access data utilized by the OS and/or various applications by providing access commands to the memory device 1693 to retrieve said data utilized in the execution of the OS and/or the various applications.

For clarity, the system has been simplified to focus on features with particular relevance to the present disclosure. The memory array 1680 can be a DRAM array comprising at least one memory cell 1610 having a sense line and shared digit line formed according to the techniques described herein. For example, the memory array 1680 can be an unshielded DL 4F2 array such as a 3D-DRAM memory array. The memory array 1680 can comprise memory cells 1610 arranged in rows coupled by access lines (which may be referred to herein as word lines or select lines) and columns coupled by sense lines (which may be referred to herein as digit lines or data lines), a sense amp 1634 and transfer gates 1689 that can function as switches. Sense amp 1634 may be provided for corresponding sense lines and connected to at least one respective local input/output (I/O) line pair (LIOT/B), which may in turn be coupled to at least respective one main I/O line pair (MIOT/B), via the transfer gates 1689. Memory device 1693 may include a number of arrays 1680 (e.g., a number of banks of DRAM cells).

Address signals are received and decoded by an address decoder 1671, a row decoder 1698 and a column control circuit 1682 to access the memory array 1680. Data can be read from memory array 1680 by sensing voltage and/or current changes on the sense lines using sensing circuitry (not pictured). The sensing circuitry can comprise, for example, sense amplifiers 1634 that can read and latch a page (e.g., row) of data from the memory array 1680. The I/O circuitry 1697 can be used for bi-directional data communication with the host over a first voltage bus 1679, a first data bus 1681, and a second data bus 1684. The read/write circuitry (read/write amplifier) 1683 is used to write data to the memory array 1680 or read data from the memory array 1680. As an example, the read/write circuitry 1683 can comprise various drivers, latch circuitry, etc.

Command control circuitry 1675 includes registers and decodes signals provided by the host. The signals can be commands provided by the host. Command address input circuitry 1673 can receive a command over a command bus 1672 and the command can be decoded by command decoder circuitry (not pictured). Although the address input circuitry 1696 and the command address input circuitry 1673 are shown as separate circuits, the address input circuitry 1696 and the command address input circuitry 1673 can be combined into a single circuit. These signals can include chip enable signals, write enable signals, and address latch signals that are used to control operations performed on the memory array 1680, including data read operations, data write operations, and data erase operations. The memory device 1693 can also include refresh control circuitry 1677 to refresh data in the memory device 1693. In various embodiments, the control circuitry is responsible for executing instructions from the host. The control circuitry can comprise a state machine, a sequencer, and/or some other type of control circuitry, which may be implemented in the form of hardware, firmware, or software, or any combination of the three. In some examples, the host can be a controller external to the memory device 1693. For example, the host can be a memory controller which is coupled to a processing resource of a computing device.

The memory device 1693 can also include clock input circuity 1685 to receive external clock signals over a clock bus 1674. The memory device 1693 can also include internal clock generator 1686 to generate an internal clock signal. Further, the memory device 1693 can include an internal voltage generator 1687 to generate various internal voltage potentials based on the power supply potentials VDD and VSS and a second voltage bus 1688 to send a receive a voltage.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” an other element, the particular element can cover the other element, can be over the other element or lateral to the other element and/or can be in direct physical contact the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A method for forming arrays of vertically stacked memory cells, having horizontally oriented access devices and access lines and shared vertically oriented digit lines, comprising:
forming a plurality of first vertical openings, having a first horizontal direction axis and a second horizontal direction axis, through a vertical stack of repeating iterations of a first dielectric material, a first semiconductor material having a first-type dopant, and a second dielectric material, the first vertical openings extending predominantly in the second horizontal direction axis to form elongated vertical, pillar columns with first vertical sidewalls in the stack;
depositing a third dielectric material in the plurality of first vertical openings;
forming a second vertical opening through the vertical stack and extending predominantly in the first horizontal direction axis to expose second vertical sidewalls adjacent a first region of the first semiconductor material;
selectively etching the second dielectric material in the second horizontal direction axis to form a plurality of first horizontal openings;
removing a portion of the third dielectric material filled in the plurality of first vertical openings, between the first horizontal openings, to form continuous second horizontal openings extending in the first horizontal direction axis;
depositing a conductive gate material on a gate dielectric material, recessed back in the plurality of first horizontal openings, in the continuous second horizontal openings to form horizontally oriented access lines opposing a channel region of the semiconductor material; and
forming a plurality of third vertical openings to depositing a second semiconductive material, having a second-type dopant, therein within the second vertical opening to form the shared vertically oriented digit lines.

2. The method of claim 1, further comprising concurrently, selectively etching the second dielectric material in two opposing directions along the second horizontal direction axis to form a plurality of first horizontal openings in opposing directions and to form two adjacent horizontal access devices sharing vertically oriented digit lines with direct electric contact to formed first source/drain regions.

3. The method of claim 2, further comprising coupling a multiplexor to the shared vertically oriented digit lines to select between the two adjacent horizontal access devices.

4. The method of claim 1, further comprising depositing a tungsten (W) material as the second semiconductive material to form vertically oriented digit lines.

5. The method of claim 1, further comprising:
gas phase doping a dopant in a top surface of the first semiconductor material to form the first source/drain region horizontally adjacent the channel region; and
depositing a fourth dielectric material in the continuous second horizontal openings adjacent the conductive gate material and the gate dielectric material.

6. The method of claim 1, further comprising:
forming a fourth vertical opening adjacent a second region of the first semiconductor material to expose third vertical sidewalls in the vertical stack;
selectively etching the first semiconductor material in the second horizontal direction axis to form a plurality of third horizontal openings in the second region;
gas phase doping a dopant in a side surface of the first semiconductor material from the third horizontal openings to form second source/drain regions horizontally adjacent the channel region; and
depositing horizontally oriented capacitor cells having a bottom electrode formed in electrical contact with the second source/drain regions.

7. The method of claim 1, wherein selectively etching the second dielectric material comprises removing the second dielectric material a first distance (DIST 1) in a range of approximately fifty (50) to one hundred and fifty (150) nanometers (nm) back from the second vertical opening.

8. The method of claim 1, further comprising selectively recessing the conductive gate material and the gate dielectric material in the second direction a second distance (DIST 2) in a range of twenty (20) to fifty (50) nanometers (nm) back from the second vertical opening.

9. The method of claim 1, further comprising selectively recessing the conductive gate material and the gate dielectric material a second distance (DIST 2) back into the continuous second horizontal openings extending in the first horizontal direction axis using an atomic layer etching (ALE) process.

10. The method of claim 1, wherein depositing the conductive gate material on the gate dielectric material, recessed back, in the continuous second horizontal openings extending in the first horizontal direction axis comprises depositing the gate dielectric and the conductive gate material using an atomic layer deposition (ALD) process.

11. The method of claim 1, further comprising depositing layers of an oxide material as the first dielectric material, a low doped, p-type (p−) polysilicon as the first semiconductor material, and a silicon nitride (SiN) material as the second dielectric material, in repeating iterations vertically, to form the vertical stack.

12. A method for forming arrays of vertically stacked memory cells, having horizontally oriented access devices and access lines and shared vertically oriented digit lines, comprising:
forming a plurality of first vertical openings, having a first horizontal direction axis and a second horizontal direction axis, through a vertical stack of repeating iterations of a first dielectric material, a first semiconductor material, and a second dielectric material, the first vertical openings extending predominantly in the second horizontal direction axis to form elongated vertical, pillar columns with first vertical sidewalls in the stack;
filling the plurality of first vertical openings with a third dielectric material;
forming a second vertical opening through the vertical stack and extending predominantly in the first horizontal direction axis to expose second vertical sidewalls adjacent a first region of the first semiconductor material;
selectively etching the second dielectric material in the second horizontal direction axis to form a plurality of first horizontal openings, separated vertically and horizontally in the stack, and separated horizontally by the third dielectric material;
removing a portion of the third dielectric material filled in the plurality of first vertical openings, laterally in-between the first horizontal openings extending in the second horizontal direction axis, to form continuous second horizontal openings extending in the first horizontal direction axis;
depositing a conductive material on a gate dielectric material, recessed back, in the continuous second horizontal openings to form horizontally oriented access lines opposing a channel region of the semiconductor material;
depositing a fourth dielectric material in adjacent the horizontally oriented access lines to fill the plurality of first horizontal openings to the second vertical opening;
depositing a polysilicon material having a second-type dopant within third vertical openings to form shared vertically oriented digit lines; and
annealing the polysilicon material to out diffuse the second-type dopant into the first semiconductor material to form first source/drain regions for the horizontally oriented access devices.

13. The method of claim 12, wherein forming the shared vertically oriented digit lines includes forming two adjacent horizontal access devices sharing vertically oriented digit lines with direct electric contact to the first source/drain regions which improves array efficiency for the digit line.

14. The method of claim 12, further comprising depositing a tungsten (W) material on the polysilicon material in the third vertical openings.

15. The method of claim 12, further comprising depositing a titanium/titanium nitride (TiN) conductive material on the polysilicon material, via the third vertical openings, to form a titanium silicide as part of the shared vertically oriented digit line coupled to first source/drain regions of the horizontally oriented access devices.

16. The method of claim 12, wherein depositing the polysilicon material having a second-type dopant in the third vertical openings comprises depositing a highly phosphorus (P) doped (n+) poly-silicon germanium (SiGe) material.

17. The method of claim 12, further comprising depositing a ruthenium (Ru) composition as the conductive material to form horizontally oriented access lines opposing a channel region of the semiconductor material.

18. A memory device, comprising:
an array of vertically stacked memory cells, the array having horizontally oriented access devices and access lines and shared vertically oriented digit lines, comprising:
horizontally oriented access devices having a first source/drain region and a second source/drain region separated by a channel region, and gates opposing the channel region and separated therefrom by a gate dielectric;
horizontally oriented access lines coupled to the gates and separated from the channel region by the gate dielectric;
horizontally oriented storage nodes electrically coupled to the second source/drain regions of the horizontally oriented access devices; and
vertically oriented digit lines, shared between two horizontal access devices in two opposing directions, electrically coupled to the first source/drain regions of the two horizontally oriented access devices.

19. The memory device of claim 18, wherein the vertically oriented digit lines comprise a highly phosphorus (P) doped (n+) poly-silicon germanium (SiGe) material.

20. The memory device of claim 18, wherein the vertically oriented digit lines comprise a tungsten (W) material formed on a titanium/titanium nitride (TiN) material which forms a titanium silicide with the first source/drain regions of the horizontally oriented access devices.

21. The memory device of claim 18, wherein the horizontally oriented access devices are gate all around (GAA) horizontal access devices.

22. The memory device of claim 18, wherein the GAA horizontal access devices comprise a conductive gate material formed fully around every surface of the channel region.

23. The memory device of claim 18, wherein the horizontally oriented access devices are dual gate horizontal access devices.
